(19) United States
(12) Patent Application Publication
(10) Pub. No.: US 2026/0372080 A1
(43) Pub. Date: Nov. 19, 2026

(54) HEAT TRANSFER SIMULATION METHOD FOR POWER SEMICONDUCTOR SWITCHING MODULE

(71) Applicant: NexFi Technology Inc., Suita-shi, Osaka (JP)

(72) Inventors: Satoshi TANIMOTO, Suita-shi, Osaka (JP); Takashi NAKAMURA, Suita-shi, Osaka (JP)

(21) Appl. No.: 19/475,806

(22) PCT Filed: Apr. 30, 2024
(86) PCT No.: PCT/JP2024/016674

§ 371 Date: Oct. 16, 2025

(30) Foreign Application Priority Data
Jul. 11, 2023 (JP) 2023-113644

(51) Int. Cl. H10W 40/20

(52) U.S. Cl. CPC H10W 40/233

(57) ABSTRACT

A heat transfer simulation method for a power semiconductor switching module includes the steps of: calculating circuit parameters of a steady-state thermal resistance Rₜₕₙ and Cₜₕₙ with respect to an n-th heat transfer layer from top in a stacked direction based on heat transfer in an up-down direction and heat transfer due to a heat spread in a lateral direction; building a ladder-type heat dissipation circuit 12 based on the circuit parameters; and numerically calculating a time response solution or a transient thermal impedance of each node with respect to the ladder-type heat dissipation circuit 12.

### TECHNICAL FIELD

The present invention relates to a heat transfer simulation method for a power semiconductor switching module on which a plurality of power semiconductor SW chips are mounted.

### BACKGROUND ART

Hereinafter, for the sake of simplicity, the following abbreviations will be used as appropriate: a time range of 1 ms (millisecond) or more and less than 1 sec (second), preferably a time range of 1 ms or more and 100 ms or less, and more preferably a time range of 1 ms or more and 60 ms or less as “ms range”; a power semiconductor switching module as “PSM”; and a switch as “SW”.

A single-pulse current-carrying PSM refers to a PSM comprising a function and a purpose of normally being in a breaking state but entering a current-carrying for an extremely short period of time in the ms range at certain times (for example, in the event of an abnormality). A typical application of the single-pulse PSM is a semiconductor breaker path in a high-power hybrid DC circuit breaker that is composed of a mechanical SW path and the semiconductor breaker path (Non-Patent Literature 1). The single-pulse PSM is applicable not only to high power application but also to medium and small power application, furthermore and also to short-time current-carrying AC power application.

Power semiconductor switching modules to which a heat transfer simulation method is applied include not only the single-pulse current-carrying PSM described above but also power semiconductor switching modules that can be used for both single-pulse current-carrying and non-single-pulse current-carrying.

Generally, current PSMs use non-single-pulse, on-off current-carrying type power semiconductor switching modules (for example, Patent Literature 1 and Non Patent Literature 1) that have been used in the past.

Here, a configuration of a conventional single-pulse PSM is roughly described. A predetermined power semiconductor SW chip (such as a power MOSFET, an IGBT, or a diode) is bonded, using a die attach such as solder, on a thin chip metal conductor placed on and bonded to an upper surface of an insulating substrate to create power semiconductor SW unit cells, and the power semiconductor SW unit cells are arranged on a single metal base plate, with a necessary number of unit cells connected in parallel to satisfy a required current capacity and a necessary number of unit cells connected in series to satisfy a required withstand voltage.

The parallel connection of the power semiconductor SW unit cells is usually achieved by sharing the chip metal conductor. On the other hand, the series connection is achieved by connecting an upper electrode of a semiconductor of an adjacent high-potential unit and a chip metal conductor of an adjacent low-potential unit with an interconnect such as a bonding wire.

### CITATION LIST

### Patent Literature

Patent Literature 1: Japanese Patent Laid-Open No. 2006-216730

### Non Patent Literature

Non Patent Literature 1: Toshiaki Matsumoto, Naotaka lio, “Direct Current Circuit Breaker (DCCB)”, IEEJ Journal, Vol. 137, No. 11 (2017), pp. 757 to 760

### SUMMARY OF INVENTION

### Technical Problem

Generally, a configuration is adopted in which the insulating substrate of the power semiconductor SW unit cells is shared (integrated) and each chip metal conductor is arranged on a single insulating substrate. In this case, the metal base plate can be omitted. A thickness of the insulating substrate is determined based on magnitudes of a voltage and a current controlled by the PSM, an intensity of a surge voltage generated during switching, mechanical strength, or heat dissipation properties. Generally, the greater the amount of electricity handled, the thicker the insulating substrate becomes.

Power semiconductor SW unit cells are used, for example, in standard PSMs with a dielectric strength of 7 kV or more and a current capacity of 350 A. In this case, a PSM is configured by arranging, for example, 4 power semiconductor SW unit cells in parallel and 10 power semiconductor SW unit cells in series.

The power semiconductor SW unit cell has a stacked structure in which a plurality of heat transfer layers are stacked on top of each other. The stacked structure is constituted of, from top to bottom in an order of lamination, a SiC power MOSFET chip (0.35 mm thick) rated at 1200 V and 90 A or higher as a power semiconductor SW, a chip metal conductor made of pure copper, a tin-silver-copper based solder die attach, an alumina insulating substrate, a heat transfer bonding material, such as a silicone-based heat-conductive sheet, and an alumina insulating substrate.

When output gate signals (voltage) are simultaneously supplied from drive circuits connected to gate electrodes of all power semiconductor SW chips, the PSM enters a current-carrying state, and when the output gate signals (voltage) are removed, the PSM changes to a breaking state.

As is well known, in non-single-pulse PSMs, it is important to minimize the number of power semiconductor SW chips and the size (area) of the PSM, subject to the restriction that all power semiconductor SW chips installed inside must not be used beyond their maximum rated junction temperature T_{jMAX}. This is to improve the driving performance and product appeal (cost performance) of the PSM. For this reason, there is a strong demand to increase the current that can be carried by each chip of the power semiconductor SW during operation (in other words, chip current rating). This demand also applies to single-pulse PSMs.

A reliable way to satisfy this demand is to build a structure that efficiently transfers a Joule heat generated by the power semiconductor SW chips toward the outside of the power semiconductor SW unit cell (in other words, outside the module). Specifically, it is to effectively reduce a sum, R_{j-c}, of each steady-state thermal resistance of element members in a heat transfer path from a surface of the power semiconductor SW chips of the power semiconductor SW unit cell to a back surface of the unit cell (insulating substrate or metal base plate).

Since the main components that dominates the module steady-state thermal resistance R_{j-c} are the power semiconductor SW chips, the chip metal conductor, the insulating substrate, and a bonding material that joins these three elements, how to reduce the thermal resistance and thickness of these materials has been a major concern in conventional non-single-pulse PSM (in other words, standard PSM) thermal design.

Even in PSMs for ms-range single-pulse power applications, the module steady-state thermal resistance R_{j-c} has traditionally been considered an important indicator of heat transfer performance, and therefore their thermal designs have been made in order to lower R_{j-c}. This means that it was recognized that lowering R_{j-c} would similarly reduce a transient thermal impedance Z_{j-c}(t) in the ms range (in the present specification, thermal impedance is defined as a concept that includes both thermal resistance and thermal reactance).

However, when thermally designing the PSM, it is insufficient to evaluate the heat transfer performances of the PSM based solely on the steady-state thermal resistance R_{j-c} as in conventional traditional thermal design. This is because heat transfer from the PSM occurs not only from the back surface of the substrate of the lowermost layer of the PSM laminate structure but also from an atmosphere-exposed surface of each layer that constitutes the PSM laminate structure.

When thermally designing a PSM that considers the rated junction temperature, since it is possible to achieve a more accurate thermal design than conventional traditional thermal design in which heat transfer occurs only from the back surface of the substrate of the lowermost layer through only the steady-state thermal resistance Ric of each layer by thermally designing the PSM so as to also take into account heat dissipation from the atmosphere-exposed surface of each layer of the PSM laminate structure, it is clear that this enables further miniaturization and more flexible material selection of the PSM.

The transient thermal impedance characteristics that form the basis for designing such transient transfer performance of PSMs are important characteristics that determine a thermal limit boundary of a safe operating range of semiconductors inside PSMs. Therefore, when productizing new PSMs suitable for applications sensitive to transient thermal impedance, it goes without saying that thermal design should take into account not only steady-state thermal resistance but also transient thermal impedance characteristics. When actually performing such transient thermal design for a PSM and determining an optimal PSM structure in terms of transient heat, a rational procedure is as follows.

In early steps when there are many parameters to consider, a first step is to use a simplified simulation to continuously vary material parameters and structural parameters over a wide range in order to understand trends in changes to transient thermal impedance characteristics, and subsequently roughly design an optimal PSM structure.

In a next second step, advanced high-precision means such as actual prototype evaluation and FEM (finite element method) heat transfer analysis are used to vary conditions within a narrow range and calibrate errors and deviations.

Such a two-step design process is desirably adopted because designing based solely on actual prototype evaluation and FEM analysis would result in high development costs and long development times. The rough structural design process using the simplified transient heat transfer simulation described in the first step above is extremely important from the perspective of reducing product costs and development and manufacturing periods, particularly when producing small quantities of PSMs or custom-made PSMs.

The conventional conduction model used when performing a simulation calculation of the transient thermal characteristics of a PSM is a one-dimensional heat transfer model. In other words, it is a model in which heat transfer occurs in only one direction (in this case, a Z-axis direction as an up-down direction (stacked direction of PSM)) and does not spread in a lateral direction (XY direction). Therefore, the following problems arise.
1) No knowledge is gained regarding heat spread that occurs in the lateral (XY direction) which is necessary for structural design.
2) In principle, a thermal resistance of each layer of a layered structure that constitutes the PSM is overestimated while a thermal capacity is underestimated, resulting in a drop in simulation accuracy.
3) A thermal interference effect originating from adjacent power semiconductor SW unit cells is ignored.
4) When longitudinal and lateral dimensions of each layer are thermally finite, the dimensional effect is ignored.
5) As a result, it is difficult to narrow down an optimal range of structural parameters to a narrow range.

An object of the present invention is to provide a heat transfer simulation method for a power semiconductor switching module that overcomes the problems described above.

### Solution to Problem

A heat transfer simulation method for a power semiconductor switching module according to the present invention is
a heat transfer simulation method for a power semiconductor switching module comprising:

a stacked structure constituted of m-number (where m is an integer greater than or equal to 2) heat transfer layers, with a power semiconductor SW chip as an uppermost heat transfer layer, in which heat generated by the power semiconductor SW chip is released from an atmosphere-exposed surface of each heat transfer layer, wherein
a ladder-type heat transfer circuit associated with the stacked structure comprises:
when a steady-state thermal resistance R and a steady-state thermal capacity C of an n-th (where 1≤n≤m) heat transfer layer in a stacking order from the top of the stacked structure are defined as R^{thn} and C^{thn}, respectively, one longitudinal circuit as a thermal resistance circuit in which the steady-state thermal resistance R^{thn} of each heat transfer layer is connected in series in the stacking order from one end to another end;
another longitudinal circuit as an atmospheric temperature circuit;
a heat flow single-pulse source that is interposed between one end of the one longitudinal circuit and one end of the other longitudinal circuit and that serves as a heat source for heat generated by the power semiconductor SW chip; and
a plurality of lateral circuits, each of which interposing, with one end of each steady-state thermal resistance R^{thn} of the one longitudinal circuit as a node, the steady-state thermal capacity C^{thn} of the heat transfer layer of the steady-state thermal resistance R^{thn} between the node and the other longitudinal circuit as a thermal capacity circuit, the heat transfer simulation method comprising:
a circuit parameter calculation step of calculating, for each n, circuit parameters of the steady-state thermal resistance R^{thn} and the steady-state thermal capacity Cₜₕₙ of the ladder-type heat dissipation circuit with respect to an n-th heat transfer layer based on heat transfer in a stacked direction of the stacked structure and heat transfer due to a heat spread in a perpendicular direction with respect to the stacked direction;
a ladder-type heat dissipation circuit building step of building the ladder-type heat dissipation circuit based on the calculated circuit parameters; and
a numerical calculation step of numerically calculating a time response solution or a transient thermal impedance of each node in the built ladder-type heat dissipation circuit.

### Advantageous Effect of Invention

According to the heat transfer simulation method for a power semiconductor switching module of the present invention, the steady-state thermal resistance Rₜₕₙ and the steady-state thermal capacity Cₜₕₙ, which are circuit parameters of the n-th heat transfer layer in the ladder-type heat transfer circuit on which the simulation is based, are calculated by taking into account not only heat transfer in the stacked direction of the stacked structure but also heat spread in the perpendicular direction with respect to the stacked direction. Accordingly, accuracy of heat transfer simulation of a power semiconductor switching module can be improved and structural design of the power semiconductor switching module can be made more precise.

### BRIEF DESCRIPTION OF DRAWINGS

FIG. 1 is a plan view of a single-pulse PSM.

FIG. 2 is a circuit diagram of a single-pulse PSM.

FIG. 3 is a longitudinal sectional view of any power semiconductor SW unit cell (hereinafter, simply abbreviated as “unit cell”) Uᵢⱼ of a single-pulse PSM.

FIG. 4 is a diagram showing a ladder-type heat transfer circuit associated with the unit cell Uᵢⱼ.

FIG. 5 is a diagram collectively showing longitudinal and lateral dimensions of unit cells according to Example 1 and Comparative Examples 1-1 and 1-2 with respect to a single-pulse PSM.

FIG. 6 is a table showing thermophysical property constants of a material of each part used in Example 1 and Comparative Examples 1-1 and 1-2.

FIG. 7 is a table showing values of a steady-state thermal resistance Rₜₕₙ and a steady-state thermal capacity Cₜₕₙ of each part obtained by applying the values in the table in FIG. 6 to an extended one-dimensional heat conduction model.

FIG. 8 is a graph obtained as a result of performing numerical calculations by substituting the values in the table in FIG. 7 into the heat transfer circuit model in FIG. 4 and simulating transient thermal impedance characteristics Z_{j-c}(t) in the ms range.

FIG. 9 is a diagram showing transient thermal impedance characteristics Z_{j-c}(t) in the ms range of Example 2 and Comparative Example 2 with respect to a single-pulse PSM.

FIG. 10 is a diagram showing a heat spread in a side view of a stacked structure.

FIG. 11A is a plan view with respect to a first effective heat transfer space.

FIG. 11B is an explanatory diagram of reference signs in the first effective heat transfer space.

FIG. 11C is a classification explanatory diagram in a plan view of an effective heat transfer space when calculating the steady-state thermal capacity Cₜₕₙ and the steady-state thermal resistance Rₜₕₙ of the first effective heat transfer space by simulation.

FIG. 12A is a plan view with respect to a second effective heat transfer space.

FIG. 12B is an explanatory diagram of reference signs in the second effective heat transfer space.

FIG. 12C is a lateral sectional view of the second effective heat transfer space.

FIG. 13A is a plan view with respect to a third effective heat transfer space.

FIG. 13B is a plan view of another third effective heat transfer space.

FIG. 13C is a diagram showing a dimension of each part of the third effective heat transfer space and the other third effective heat transfer space in a side view.

FIG. 13D is a diagram showing a correspondence relationship between a plan view and a side view of the third effective heat transfer space or the other third effective heat transfer space.

FIG. 14 is a plan view with respect to a fourth effective heat transfer space.

FIG. 15 is a plan view with respect to a fifth effective heat transfer space.

FIG. 16 is a plan view with respect to a sixth effective heat transfer space.

FIG. 17 is a flow chart of a heat transfer simulation method for a power semiconductor switching module.

### DESCRIPTION OF EMBODIMENTS

A plurality of suitable embodiments of the present invention will be described in detail with reference to the drawings. It is needless to say that the present invention is not limited to the following embodiments. In addition to the following embodiments, the present invention includes various configurations and aspects within the scope of the technical concept of the present invention. Throughout the drawings, the same elements are denoted by the same reference signs.

First, an example of a PSM to which a heat transfer simulation method for a power semiconductor switching module according to an embodiment is applied will be described. While a PSM of which an ms range is within a range of 1 ms or more and 60 ms or less is selected as the PSM according to the example, the heat transfer simulation method according to the present invention can also be applied to PSMs with an ms range exceeding 60 ms and less than 1 sec.

The present applicant has proposed, in a separate application from the present application, a power semiconductor switching module that can be miniaturized and enables cost reduction by considering not only heat transfer involving conducting heat generated by a power semiconductor SW chip to an insulating substrate but also heat transfer from a surface exposed to an atmospheric space of a layered body interposed between the power semiconductor SW chip and the insulating substrate (reference: International Publication No. 2023/181761). The following embodiment is applied to, for example, the proposed power semiconductor switching module.

### (Power Semiconductor Switching Module)

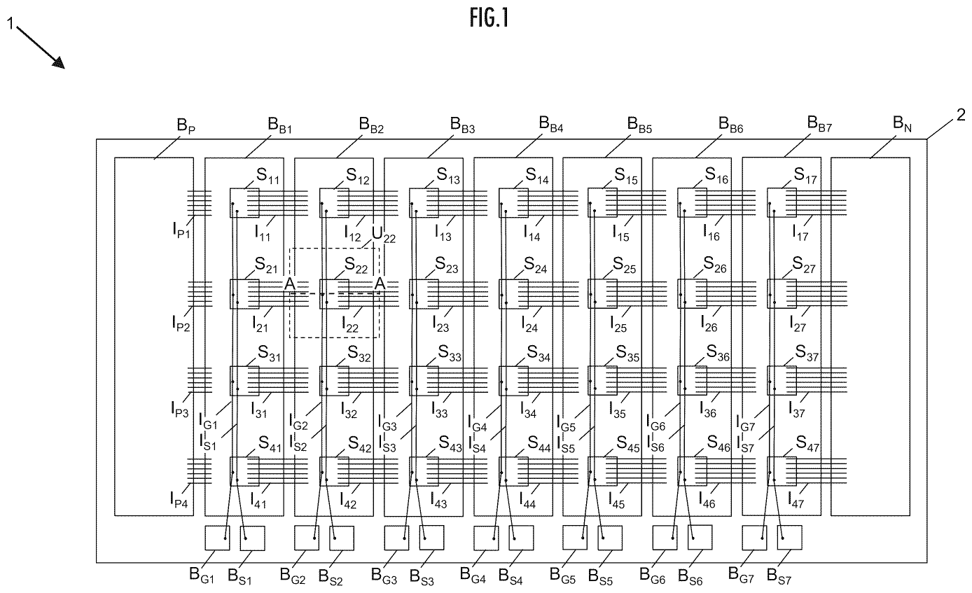

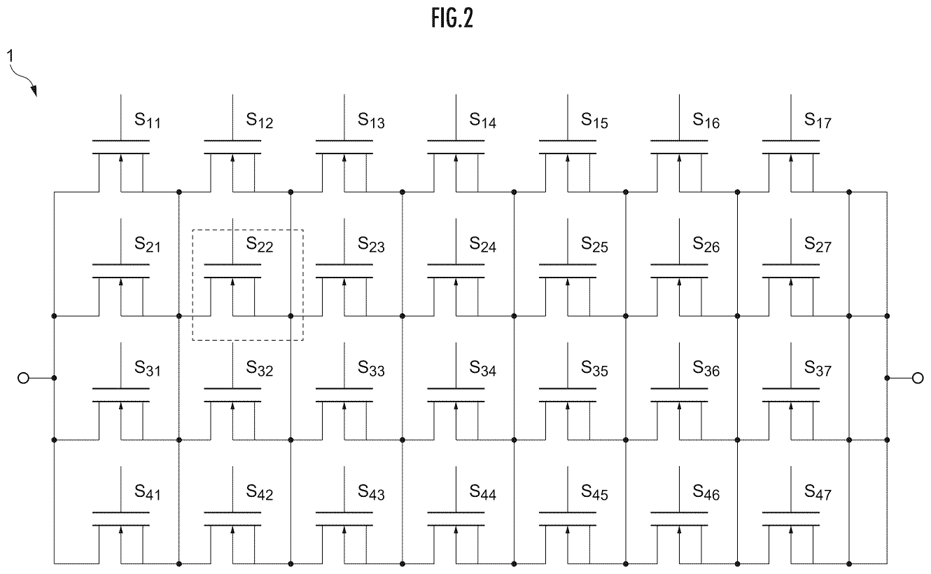

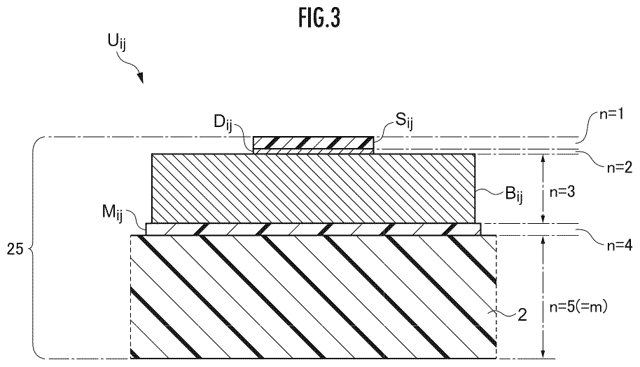

FIG. 1 is a plan view of a single-pulse current-carrying power semiconductor switching module (single-pulse PSM) 1, FIG. 2 is a circuit diagram of the single-pulse PSM 1, and FIG. 3 is a longitudinal sectional view of any power semiconductor SW unit cell (hereinafter, simply abbreviated as “unit cell”) Uᵢⱼ of the single-pulse PSM 1. In “Uᵢⱼ”, the subscripts i and j denote an address (row i, column j) of the unit cell in FIGS. 1 and 2. Note that, hereinafter, the subscripts i and j attached to reference signs of parts other than unit cells also have similar meanings.

While the single-pulse PSM 1 in FIGS. 1 and 2 represents an example in which 7 unit cells Uᵢⱼ are connected in series and 4 unit cells Uᵢⱼ are connected in parallel, the numbers of series and parallel connections are merely an example for explanatory purposes and any combination of parallel and series connections is acceptable as long as there are two or more unit cells.

The basic structure of the unit cells Uᵢⱼ is essentially the same. However, it is also possible to configure a modified version that combines different type power semiconductor switches. In such cases, the configurations of different type power semiconductor switch unit cells are to differ. A common scenario in practice is to place a power diode in antiparallel with a power transistor. In such cases, for example, the power semiconductor switch of the unit cell Uᵢⱼ in an even-numbered i-th row is made a power transistor and the power semiconductor switch of the unit cell Uᵢⱼ in an odd-numbered i-th row is made a power diode.

Proceeding to a detailed description of a unit cell structure, in FIG. 3, Sᵢⱼ is a thin power semiconductor SW chip that is bonded to a thick chip metal conductor Bᵢⱼ via a thin die attach Dᵢⱼ. The chip metal conductor Bᵢⱼ, which has the same column number j, is actually integrated as B_{Bj} as shown in FIG. 1 in order to connect the power semiconductor SW chips Sᵢⱼ in the same column in parallel. Each chip metal conductor B_{Bj} is bonded to a common insulating substrate 2 via a heat transfer bonding material M_{Bj} (a reference sign of M_{Bj} is not illustrated).

B_{P} denotes a P-terminal metal conductor for attaching a P terminal (not illustrated) of a main circuit, B_{N} denotes an N-terminal metal conductor for attaching the N terminal (not illustrated) of the main circuit, and B_{Gj} and B_{Sj} each denote a control terminal metal conductor for attaching an input terminal (not illustrated) of a gate/source signal line for controlling turn-on/turn-off of the power semiconductor SW chip Sᵢⱼ of the j-th column unit cell. The P-terminal metal conductor B_{P}, the N-terminal metal conductor B_{N}, and the control terminal metal conductors B_{Gj} and B_{Sj} are bonded to the common insulating substrate 2 via a heat transfer bonding material (not illustrated) in a similar manner to the chip metal conductor Bᵢⱼ.

Iᵢⱼ is a main circuit interconnect for connecting, in series, the power semiconductor SW chip Sᵢⱼ and Sᵢⱼ₊₁, which is adjacent to the right to Sᵢⱼ in the diagram and, for example, Iᵢⱼ is a thick aluminum bonding wire that connects an upper surface electrode of Sᵢⱼ and the chip metal conductor B_{Bj+1} of the unit cell adjacent to the right. I_{Pj} is a main circuit interconnect for connecting the P-terminal metal conductor B_{P} and a 1st column chip metal conductor Bᵢₗ which is adjacent to the right to the P-terminal metal conductor B_{P} and, for example, Iᵢⱼ is a thick aluminum bonding wire I_{Gj} and I_{Sj} are signal line interconnects for connecting a pair of control signal electrodes (gate electrode, Kelvin source electrode, or the like) of the chip metal conductor Bᵢⱼ arranged in the j-th column and are, for example, a thin aluminum bonding wire. Note that a thick wire and a thin wire refer to thicknesses of the aluminum bonding wire.

When a single-pulse PSM with divided insulating substrates 2 is to be constructed for some purpose, a configuration can be adopted in which a common base metal substrate is prepared and a plurality of divided insulating substrates 2 are placed on top of the common base metal substrate as described in Patent Literature 1.

A feature of the single-pulse PSM 1 according to the embodiment shown in FIGS. 1 to 3 is that the single-pulse PSM 1 is optimized to effectively reduce transient thermal impedance in the ms range. Compared to conventional single-pulse PSMs, this optimization results in significant differences in the attributes of the power semiconductor SW chip Sᵢⱼ, the die attach Dᵢⱼ, and the chip metal conductor Bᵢⱼ.

The power semiconductor SW chip Sᵢⱼ is any semiconductor such as SiC, GaN, or Si. For example, a low-resistance power transistor such as a MOSFET or an IGBT or a low-resistance power diode such as a pn diode or a Schottky diode can be used.

In order to reduce the ms-range transient thermal impedance of the PSM unit cell, it is desirable that the thickness of the power semiconductor SW chip Sᵢⱼ be as thin as possible with an effective device layer thickness of a power semiconductor SW as a lower limit at, even if thick, 0.25 mm or less, and preferably 0.2 mm or less.

As is well known, a power semiconductor SW is formed on a surface layer of a semiconductor substrate. An effective device layer thickness refers to the thickness of the power semiconductor SW layer. Since the power semiconductor SW can no longer function as a SW element as the thickness of the power semiconductor SW chip approaches the effective device layer thickness, the effective device layer thickness must be greater than the thickness of the power semiconductor SW. It is known that the effective device layer thickness tends to be thicker in semiconductor materials with a small energy bandgap (or intrinsic breakdown field).

Next, as the die attach Dᵢⱼ, bonding materials that guarantee low resistance such as solder (Sn—Ag—Cu based, Pb based, Sn—Cu based, and Au based solder), sintered Ag paste, and sintered Cu paste can be used. However, the die attach Dᵢⱼ is not limited to these materials and other low-resistance materials may also be used.

In order to achieve a reduction in ms-range transient thermal impedance, in the example of an object of application of the heat transfer simulation method, it is desirable that the thickness of the die attach Dᵢⱼ be as thin as possible at 0.07 mm or less and preferably 0.05 mm or less. A practical lower limit of the thickness is determined by industrial stability and cost of the joining technique.

Next, a base metal material exhibiting low resistance and good thermal conductivity can be used for the chip metal conductor Bᵢⱼ. While Cu or Al is an example of a material that fits this description, other base metals can also be used. The surface of the chip metal conductor may be plated with Ni, Au, Ag, or Pt in order to improve the bond with the die attach Dᵢⱼ.

In order to achieve a reduction in ms-range transient thermal impedance of the PSM (unit cell), in the example of an object of application of the heat transfer simulation method, it is desirable that the thickness of the chip metal conductor Bᵢⱼ ranges from at least 0.8 mm or more to 5 mm or less and more preferably 1.5 mm or more to 3 mm or less.

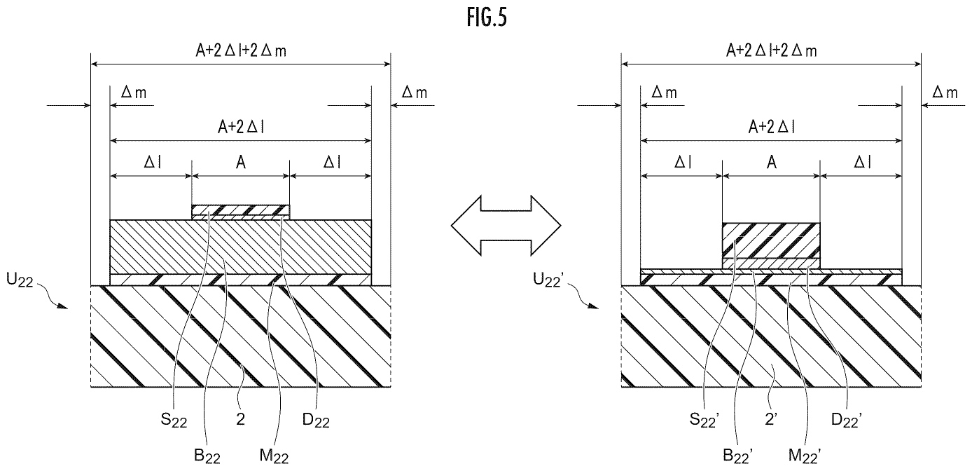

Furthermore, in order to reduce the ms-range transient thermal impedance, an outer edge of the chip metal conductor Bᵢⱼ is desirably increased by an increment Δ1 (refer to FIG. 5) in a range of 1.1 mm to 5.1 mm as compared to an outer edge of the power semiconductor SW chip Sᵢⱼ and more preferably increased by only Δ1=2.1 mm to 4.1 mm. When a longitudinal length and a lateral length of the power semiconductor SW chip Sᵢⱼ are denoted by A and B, a longitudinal length of the chip metal conductor Bᵢⱼ is A+2Δ1 and a lateral length is B+2Δ1.

There are no major constraints on the heat transfer bonding material Mᵢⱼ as long as normal heat transfer properties are provided and the heat transfer bonding material Mᵢⱼ can be selected relatively freely from among conventional heat transfer bonding materials. Silicone-based thermally conductive sheets and solders (Sn—Ag—Cu based, Pb based, and Sn—Cu based solders) fit this description. When using solder as a heat transfer bonding material, it is assumed that the surface of the insulating substrate 2 is metallized. There are no particular requirements regarding the thickness of the heat transfer bonding material and; for example, the thickness may range from 0.1 mm to 0.3 mm.

For the insulating substrate 2, an insulating substrate with the same specifications as conventional PSMs can be selected in a similar manner to conventional single-pulse PSMs, taking into consideration breakdown strength to ground and mechanical strength. For example, an insulating substrate made of alumina which is an inexpensive material can be used. In the single-pulse PSM according to the example of an object of application, silicon nitride substrates or aluminum nitride substrates (both of which are relatively expensive) with higher thermal conductivity than alumina insulating substrates need not be deliberately adopted.

### (Ladder-Type Heat Dissipation Circuit)

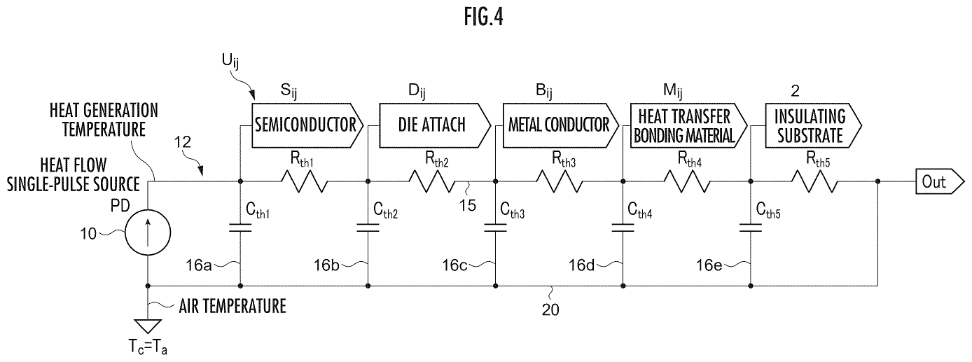

FIG. 4 is a diagram showing a ladder-type heat transfer circuit 12 associated with the unit cell Uᵢⱼ. In the heat transfer simulation for power semiconductor switching modules according to the embodiment, heat spread is considered in each heat transfer layer in a perpendicular direction (a direction parallel to upper and lower surfaces as main surfaces of the heat transfer layer) with respect to the thickness direction of the heat transfer layer (a stacked direction and also an up-down direction of the stack). While the heat spread will be described in detail in FIG. 10 and thereafter, a brief description will now be provided for ease of understanding of the ladder-type heat dissipation circuit 12 shown in FIG. 4.

In a heat transfer circuit with a stacked structure such as the unit cell Uᵢⱼ, thermal conductivity of n-th and n+1-th heat transfer layers from the top are defined as λₙ and λₙ₊₁, respectively. Heat transmitted from a heat incidence surface on the upper surface of the n-th heat transfer layer to the n-th heat transfer layer spreads in a perpendicular direction with respect to the stacked direction (up-down direction). If a heat spread angle of the heat on the surface of the n-th heat transfer layer is denoted by α (FIG. 10), α is calculated by α=tan⁻¹ (λₙ/λₙ₊₁). Note that the heat spread angle in the stacked direction is α=0° and the heat spread angle in the perpendicular direction (radial direction) with respect to the stacked direction is α=90°.

When the heat spread angle α is small and a thickness of the heat transfer layer is relatively thin but a dimension in the radial direction is sufficiently larger than the heat incidence surface, heat transfer on the heat transfer layer proceeds from the upper surface to the lower surface of the heat transfer layer while maintaining the heat spread. In contrast, when the heat spread angle α is large and the thickness of the heat transfer layer is relatively thick but the dimension in the radial direction is not sufficiently larger than the heat incident surface, since heat transfer in the heat transfer layer reaches a side surface of the heat transfer layer at a predetermined thickness direction position and is released (physically insulated) from the surface of the side surface into atmospheric space, heat spread does not occur at positions below the predetermined thickness direction position in the heat transfer layer but proceeds toward the next heat transfer layer.

Heat transfer inside each heat transfer layer is determined by the steady-state thermal resistance Rₜₕₙ described later for each heat transfer layer. The thermal capacity of each heat transfer layer is determined by the steady-state thermal capacity Cₜₕₙ described later for each heat transfer layer.

Next, a calculation method of the transient thermal impedance Z_{j-c} of the unit cell Uᵢⱼ will be described. First, the thermophysical property constants and dimensions of each layer (power semiconductor SW chip and die attach, chip metal conductor, heat transfer bonding material, and insulating substrate) of the power semiconductor SW unit cell are entered into an extended one-dimensional heat transfer model to determine the steady-state thermal capacity Cₜₕₙ (unit: J/K) and the steady-state thermal resistance Rₜₕₙ (unit: K/W) for each layer. Note that the extended one-dimensional heat transfer model is defined as a heat transfer model that also considers heat conduction of a heat spread in a perpendicular direction with respect to the up-down direction, unlike a one-dimensional conduction model in which heat conduction occurs only in the up-down direction.

In FIG. 3 described earlier, the stacked structure 25 is constituted of m-number (in the illustrated example, m=5) of heat transfer layers. When the m-number of heat transfer layers are numbered n (1≤n≤m) in the order of stacking from top to bottom, the first heat transfer layer is the power semiconductor SW chip Sᵢⱼ, the second heat transfer layer is the die attach Dᵢⱼ, the third heat transfer layer is the chip metal conductor Bᵢⱼ, the fourth heat transfer layer is the heat transfer bonding material Mᵢⱼ, and the fifth heat transfer layer is the insulating substrate 2. The first heat transfer layer means an uppermost layer of the stacked structure 25 and the fifth heat transfer layer means a lowermost layer of the stacked structure 25.

Once the steady-state thermal capacity Cₜₕₙ and the steady-state thermal resistance Rₜₕₙ of each heat transfer layer have been determined, these values are substituted into the variables of the ladder heat transfer circuit model shown in FIG. 4. A specific calculation method will be described in FIG. 10 and thereafter.

In FIG. 4, the ladder-type heat transfer circuit 12 includes a thermal resistance circuit 15 that constitutes one longitudinal circuit, an atmospheric temperature circuit 20 that constitutes another longitudinal circuit, and thermal capacity circuits 16a, 16b, 16c, 16d, and 16e as a plurality of lateral circuits which are associated with the plurality of heat transfer layers of the stacked structure 25 and which connect the thermal resistance circuit 15 and the atmospheric temperature circuit 20.

The thermal resistance circuit 15 is connected to a heat flow single-pulse source 10 at one end and is constituted of a thermal circuit in which thermal resistances Rₜₕ₁, Rₜₕ₂, Rₜₕ₃, Rₜₕ₄, and Rₜₕ₅ of the respective heat transfer layers are connected in series in the order of the stacking sequence from top to bottom of the stacked structure from one end to the other end. The thermal resistances Rₜₕ₁, Rₜₕ₂, Rₜₕ₃, Rₜₕ₄, and Rₜₕ₅ are thermal resistances of the power semiconductor SW chip Sᵢⱼ, the die attach Dᵢⱼ, the chip metal conductor Bᵢⱼ, the heat transfer bonding material Mᵢⱼ, and the insulating substrate 2, respectively. While the heat flow single-pulse source 10 is typically a constant heat flow pulse source, pulses output by the heat flow single-pulse source 10 may have any shape.

The atmospheric temperature circuit 20 corresponds to a ground line of an electrical circuit, and the atmospheric temperature is the temperature of the back surface of the unit cell Uᵢⱼ exposed to an atmospheric space. Thermal capacity Cₜₕ₁, Cₜₕ₂, Cₜₕ₃, Cₜₕ₄, and Cₜₕ₅ are thermal capacities of the power semiconductor SW chip Sᵢⱼ, the die attach Dᵢⱼ, the chip metal conductor Bᵢⱼ, the heat transfer bonding material Mᵢⱼ, and the insulating substrate 2, respectively, and the heat of each heat transfer layer is equivalent to the heat that is directly released from the atmosphere-exposed back surface of the heat transfer layer into the atmospheric space without being transferred to the underside of the heat transfer layer, and physically corresponds to the heat that is temporarily accumulated in the heat transfer layer.

With respect to heat generated by the power semiconductor SW chip Sᵢⱼ during single-pulse current carrying in the ms range, the thermal impedance Zᵢⱼ of the ladder-type heat dissipation circuit 12 is set so as to maintain the power semiconductor SW chip Sᵢⱼ at or below the maximum rated junction temperature by the heat transfer through the entire ladder-type heat transfer circuit 12 constituted of the thermal resistance circuit 15 and the thermal capacity circuits 16a, 16b, 16c, 16d, and 16e regardless of whether or not heat dissipation through only the thermal resistance circuit 15 can maintain the power semiconductor SW chip Sᵢⱼ at or below the maximum rated temperature.

Note that “set so as to maintain the power semiconductor SW chip Sᵢⱼ at or below the maximum rated junction temperature by the heat dissipation through the entire ladder-type heat transfer circuit 12 constituted of the thermal resistance circuit 15 and the thermal capacity circuits 16a, 16b, 16c, 16d, and 16e regardless of whether or not heat dissipation through only the thermal resistance circuit 15 can maintain the power semiconductor SW chip Sᵢⱼ at or below the maximum rated temperature” can be taken when the power semiconductor SW chip Sᵢⱼ cannot be maintained at or below the maximum rated junction temperature solely by heat dissipation through only the thermal resistance circuit 1 and/or when the power semiconductor SW chip Sᵢⱼ can be maintained at or below the maximum rated junction temperature even by heat transfer n through only the thermal resistance circuit 15.

The maximum rated junction temperature T_{jMAX} ranges from 75 to 125 °C for Si-IGBTs and 125 to 175 °C for SiC and GaN, respectively. In addition, the thermal impedance Zᵢⱼ is calculated from the thermal resistances Rₜₕ₁, Rₜₕ₂, Rₜₕ₃, Rₜₕ₄, and Rₜₕ₅ and the thermal capacities Cₜₕ₁, Cₜₕ₂, Cₜₕ₃, Cₜₕ₄, and Cₜₕ₅ connected between the temperature of the heat flow single-pulse source 10 and atmospheric temperature.

In the ladder-type heat transfer circuit 12 shown in FIG. 4, a step response Tⱼ(t) of a surface junction temperature Tⱼ of the power semiconductor SW chip Sᵢⱼ when the surface of the power semiconductor SW chip Sⱼⱼ is heated at a constant power PD (unit: W) from time zero is determined by calculation. The following relationship (Equation 1) exists between Tⱼ and Z_{j-c} at any given time t and the Joule heating PD (constant, unit W) of the power semiconductor SW chip. Therefore, dividing each point on the Tⱼ(t) curve by PD yields the transient thermal impedance characteristic Z_{j-c}(t).

Tⱼ(t)=Z_{j-c}(t)×PD (Equation 1)

### Example 1 of PSM of Object of Application

Example 1 is an example of a single-pulse PSM mounted with a SiC MOSFET (chip size 4.8×4.8 mm²) as the power semiconductor SW chip Sᵢⱼ of the unit cell Uᵢⱼ. The die attach Dᵢⱼ is a Sn—Ag—Cu based SAC304 solder, the chip metal conductor Bᵢⱼ is pure Cu, the heat transfer bonding material Mᵢⱼ is a silicone based heat conduction sheet, and the insulating substrate 2 is an alumina plate. This material composition is the same for Comparative Examples 1-1 and 1-2 for comparison.

The thickness of Sᵢⱼ was set to 0.15 mm, the thickness of Dᵢⱼ was set to 0.02 mm, and the thickness of Bᵢⱼ was set to 3 mm. Similarly, in accordance with the description of the present invention, the length of one side of Bᵢⱼ was set to 13.5 mm (Δ1=4.1 mm). On the other hand, in consideration of commercially-available single-pulse PSMs, the thickness of Sᵢⱼ was set to 0.35 mm, the thickness of Dᵢⱼ was set to 0.1 mm, and the thickness of Bᵢⱼ was set to 0.3 mm in Comparative Examples 1-1 and 1-2. The length of one side of Bᵢⱼ was set to be the same as Bᵢⱼ to 13.5 mm (Δ1=4.1 mm).

The dimensions of the heat transfer bonding material Mᵢⱼ and the insulating substrate 2 were standardized in Example 1 and Comparative Example 1-1, in which the thickness of the heat transfer bonding material Mᵢⱼ was 0.1 mm, one side was 13.5 mm, the thickness of the insulating substrate 2 was 5 mm, and one side was 14.8 mm. In Comparative Example 1-2, in order to reduce the steady-state thermal resistance R_{j-c} in accordance with the conventional thermal design method (a method of thermally designing the PSM based solely on the steady-state thermal resistance R_{j-c} without considering the steady-state thermal capacity C), the thickness of the insulating substrate 2 was made thinner than in Comparative Example 1-1 to 3 mm. Other values are the same as in Comparative Example 1-1.

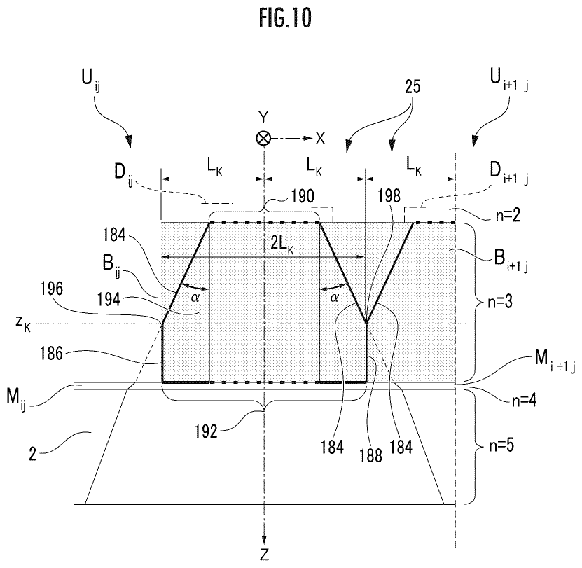

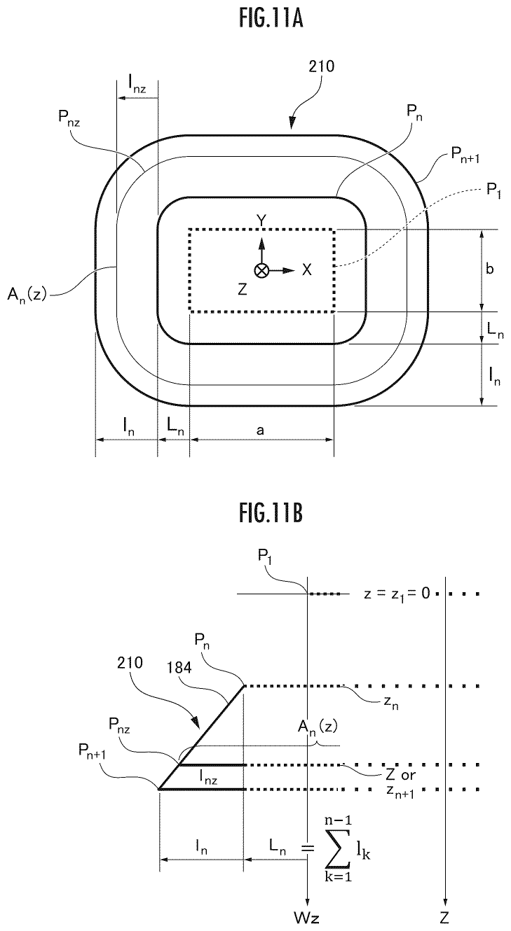

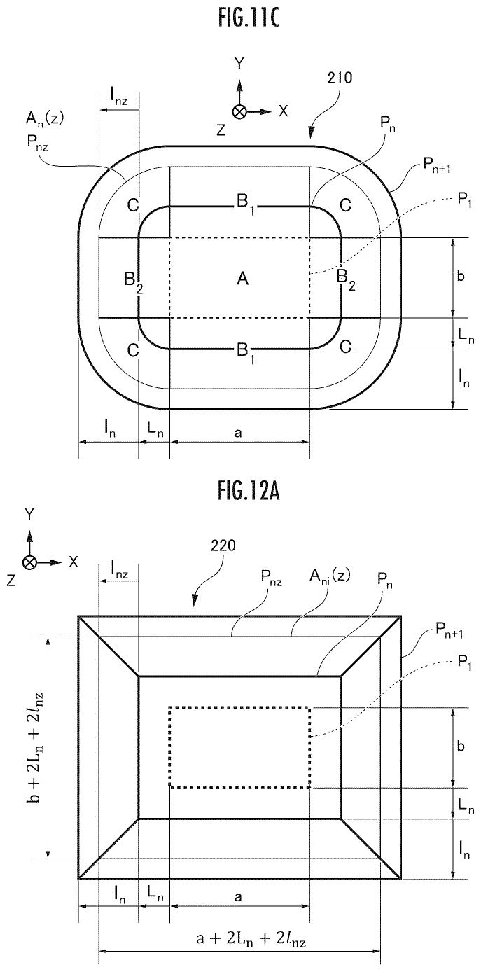

FIG. 5 collectively shows longitudinal and lateral dimensions of unit cells of a PSM (left) according to Example 1 and a PSM (right) according to Comparative Examples 1-1 and 1-2. A denotes a length of one side of the power semiconductor SW chip Sᵢⱼ, where A=4.8 mm, “a” (refer to “a” in FIG. 11A. The difference between “a” and A in FIG. 5 will be described later.) denotes the length of one side of the heat-generating surface (in other words, the effective heat transfer surface) of the power semiconductor SW chip Sᵢⱼ, where “a”=4.6 mm, and Δl denotes the distance between an outer edge of Sij and an outer edge of the chip metal conductor Bᵢⱼ, where Δ1=4.1 mm. Δm denotes a distance between the outer edge of the chip metal conductor Bᵢⱼ and an outer edge of the unit cell Uᵢⱼ, where Δm=0.9 mm. 2Δm, which is twice Δm, corresponds to an insulation distance between the chip metal conductor Bᵢⱼ and the chip metal conductor Bᵢⱼ₊₁ adjacent to the right of the chip metal conductor Bᵢⱼ in the drawing.

The difference between A and “a” will be additionally explained. The reference sign “a” denotes a heat generating portion of the power semiconductor SW chip Sᵢⱼ, and as defined in FIG. 11A and the like to be described later, “a” corresponds to a lateral width of the upper surface of the effective heat transfer space of the power semiconductor SW chip Sᵢⱼ. In contrast, A denotes a lateral width of the rectangular power semiconductor SW chip Sᵢⱼ. Since heat generation occurs inside the power semiconductor SW chip Sᵢⱼ, a<A is satisfied. Since A≈ a in the example shown in FIG. 5, illustration of “a” is omitted in FIG. 5. Note that A is distinguished from Aₙ(z) (an area in a plan view of an n-th effective heat transfer space at coordinate z on the Z axis) to be described later.

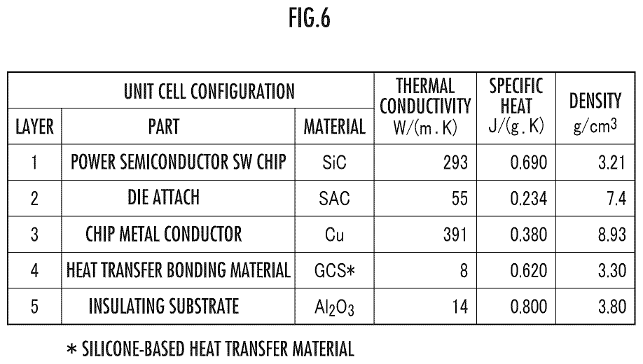

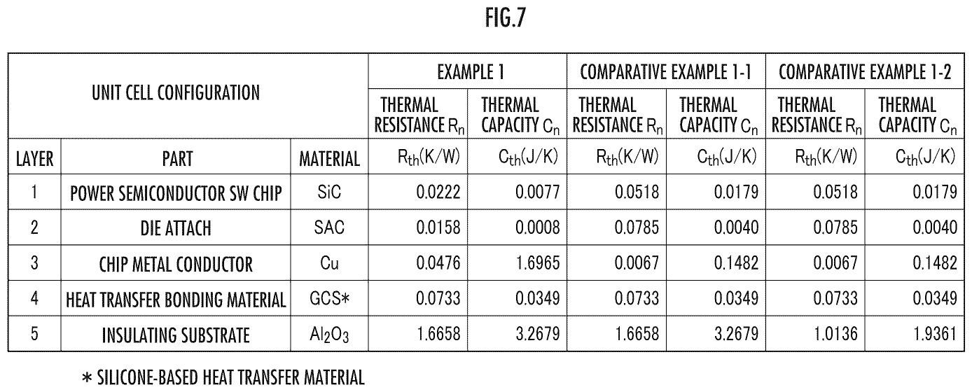

The table in FIG. 6 shows thermophysical property constants of a material of each part used in Example 1 and Comparative Examples 1-1 and 1-2. When the thermophysical property constants and dimensions (thickness and longitudinal and lateral widths) of each part are entered into the extended one-dimensional heat transfer model, the steady-state thermal capacity Cₜₕₙ and the steady-state thermal resistance Rₜₕₙ of each part are obtained as shown in the table in FIG. 7.

A graph in FIG. 8 represents a result of performing numerical calculations by substituting these values into the heat dissipation circuit model in FIG. 4 and simulating transient thermal impedance characteristics Z_{j-c}(t) in the ms range. An axis of abscissa represents heat generation time (unit: seconds). In the graph, a solid line indicates the transient thermal impedance characteristics of Example 1, while the dashed line and dashed-dotted line show the transient thermal impedance characteristics of Comparative Examples 1-1 and 1-2, respectively. The transient thermal impedance characteristics of Comparative Example 1-1 and Comparative Example 1-2 are so similar that it is difficult to distinguish between them until around 30 ms.

It is shown that the transient thermal impedance Z_{j-c} in Example 1 is significantly reduced as compared to Comparative Examples 1-1 and 1-2 in a time range of 1 ms or more. For example, since a comparison at 10 ms shows that Z_{j-c}=0.149 K/W in Comparative Example 1-1, Z_{j-c}=0.149 K/W also in Comparative Example 1-2, but Z_{j-c}=0.043 K/W in Example 1, it is demonstrated that the transient thermal impedance of the power semiconductor switching module in the example of the object of application has been reduced to less than ⅓ of the conventional value.

Referring to (Equation 1) described earlier, the fact that the transient thermal impedance Z_{j-c} has been reduced to ⅓ means that even if Joule heating of the power semiconductor SW chip Sᵢⱼ is increased threefold, the same maximum rated surface temperature T_{jMAX} of the power semiconductor SW chip can be maintained. Considering this finding, and taking into account that the Joule heating of the power semiconductor SW chip Sᵢⱼ is represented by the product of a load current I flowing through the Sᵢⱼ and an applied voltage V, Example 1 means that even with a power semiconductor SW chip having a same chip area, the power semiconductor SW chip can carry a larger load current than Comparative Example 1-1, or in other words, the current density can be increased.

Since the Joule heating when the on-resistance of a MOSFET is Ron is expressed by I²Ron, being able to triple the heating means that the load current can be increased by a factor of √3 (73% increase).

Since the transient thermal impedance is reduced and the chip current density is increased as described above, the number of power semiconductor SW chips or the area of power semiconductor SW chips can be reduced, and since the reduction enables a reduction in the area of the unit cell to be achieved, miniaturization and cost reduction of the PSM are achieved.

In the thinking of conventional single-pulse PSM thermal design, lowering the steady-state thermal resistance R_{j+c} leads to a reduction in the transient thermal impedance Z_{j-c}(t) in the ms range. In contrast, when comparing the steady-state thermal resistance R_{j-c} of Example 1 and Comparative Example 1-2, since R_{j-c} is the sum of the steady-state thermal resistances Rₜₕₙ of each layer from the surface of the power semiconductor SW chip to the back surface of the insulating substrate, adding together the Rₜₕₙ of each layer with reference to FIG. 7 yields R_{j-c}=1.825 K/W in Example 1 and R_{j-c}=1.224 K/W in Comparative Example 1-2, indicating that Comparative Example 1-2 provides a lower steady-state thermal resistance. According to conventional thermal design guidelines, while Comparative Example 1-2 should provide a lower Z_{j-c} even in the ms range, in reality, Example 1 that exhibits high steady-state thermal resistance conversely provides a much lower Z_{j-c} as described above.

The heat transfer simulation method for power semiconductor switching modules according to the present invention is particularly advantageous when calculating the optimal Z_{j-c} by combining the steady-state thermal resistance and the steady-state thermal capacity in PSMs with an ms range of 1 ms or more and 60 ms or less as in Example 1 and Example 2 to be described below. However, the heat transfer simulation method for power semiconductor switching modules according to the present invention is not limited to the application of PSMs in such a ms range, but also exhibits excellent effects in the application of PSMs in a ms range of 1 ms or more and less than 1 sec.

### Example 2 of PSM of Object of Application

A single-pulse PSM according to Example 2 is a PSM that has a GaN power semiconductor SW chip with a higher yield strength and slightly lower thermal conductivity than SiC in a unit cell. While the power device chip under consideration is a vertical MOSFET chip with a side length of 4.8 mm formed on a GaN single crystal substrate, a bipolar transistor chip or a Schottky diode chip may also be used.

The thickness of the vertical GaN-MOSFET chip is to be 0.15 mm which is in accordance with the purpose described earlier, and which is a minimum thickness that can be manufactured using today's advanced power GaN semiconductor device manufacturing techniques. The configuration of portions of the PSM unit cell other than the power semiconductor SW chip is the same as in Example 1 (FIGS. 3 and 5).

Comparative Example 2 to be compared with Example 2 assumes a case where a GaN power semiconductor SW chip with a thickness of 0.35 mm (in other words, normal thickness) is used, and the configuration of portions other than the power semiconductor SW chip is the same as that of Comparative Example 1-1 described above.

Thermophysical property values of GaN single crystals required for simulating the transient thermal impedance characteristics Z_{j-c}(t) are as follows. Thermal conductivity: 168 W/(m·K), specific heat: 0.459 J/(g·K), and density: 6.15 g/cm³.

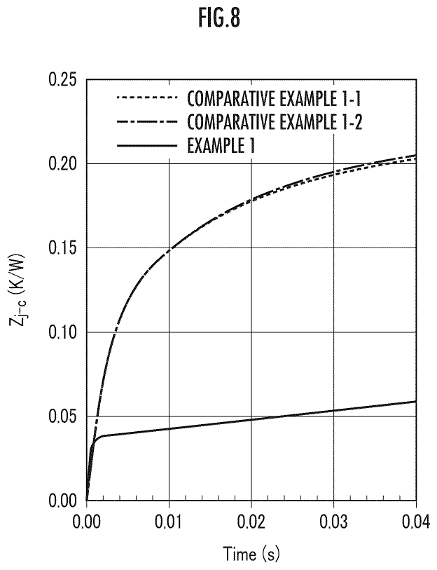

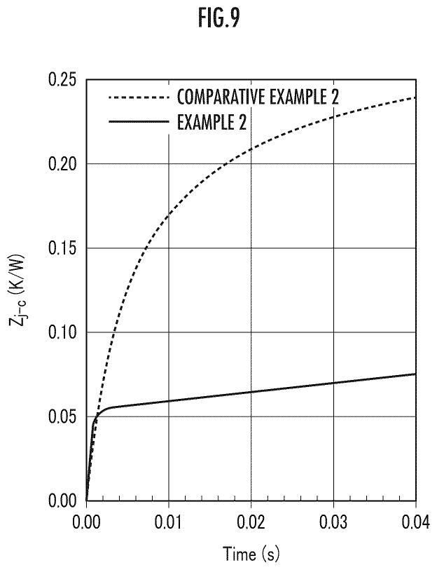

FIG. 9 shows transient thermal impedance characteristics Z_{j-c}(t) in the ms range of Example 2 and Comparative Example 2. In the graph, a solid line indicates the transient thermal impedance characteristics of (a unit cell of) Example 2, while a dashed line indicates the transient thermal impedance characteristics of (a unit cell of) Comparative Example 2.

It is shown that the transient thermal impedance Z_{j-c} in Example 2 is significantly reduced as compared to the PSM according to Comparative Example 2 in a time range of 1 ms or more. For example, since a comparison at 10 ms shows that Z_{j-c}=0.1695 K/W in Comparative Example 2 but Z_{j-c}=0.0597 K/W in Example 1, it is demonstrated that the transient thermal impedance in the example of the object of application has been reduced to ⅓ or less.

In addition, by reducing the transient thermal impedance to ⅓, the load current of the GaN-MOSFET can be increased by approximately √3 times (73%) compared to the PSM according to Comparison Example 2. Furthermore, since the chip current density can be increased compared to Comparative Example 2, not only is it possible to reduce the number of GaN-MOSFET chips or reduce the area of the GaN-MOSFET chips mounted on the PSM but the reduction also achieves a reduction in the area of the unit cell, thereby achieving miniaturization and cost reduction of the PSM.

### (Heat Spread)

Next, a basic technical concept of heat spread in the heat transfer simulation method according to the present invention will be described. FIG. 10 is a diagram showing a heat spread in a side view of the stacked structure 25. FIG. 10 shows the unit cell Uᵢⱼ and Uᵢ₊₁ⱼ that is adjacent to the unit cell Uᵢⱼ in the column direction. Therefore, FIG. 10 shows two stacked structures 25: the stacked structure 25 of the unit cell Uᵢⱼ and the stacked structure 25 of Uᵢ₊₁ⱼ. In FIG. 10, an adiabatic boundary of the chip metal conductor Bᵢⱼ as a third (n=3) heat transfer layer of the unit cell Uᵢⱼ will be described.

In each stacked structure 25, a three-axis orthogonal coordinate system with a center of the upper surface of the power semiconductor SW chip Sᵢⱼ as the origin is defined. A Z-axis extends in the up-down direction from the origin, with a positive direction being downward in the stacked direction of the stacked structure 25. In addition, the power semiconductor SW chip Sᵢⱼ is approximately rectangular in a plan view (FIG. 1), and an X-axis and a Y-axis are defined as the directions parallel to one side and another side of two adjacent sides of the rectangle, respectively. In FIG. 1, the X-axis is a direction parallel to a column direction of a grid array of the power semiconductor SW chip Sᵢⱼ and the Y-axis is a direction parallel to a row direction of the grid array of the power semiconductor SW chip Sᵢⱼ. Coordinates in the three-axis orthogonal coordinate system are expressed as (x, y, z). In FIG. 10, as appropriate, the X-axis direction and the Y-axis direction will be referred to as a lateral direction and a longitudinal direction, respectively, and dimensions in the X-axis direction and the Y-axis direction will be referred to as a lateral width and a longitudinal width, respectively.

Adiabatic boundaries include intrinsic adiabatic boundaries and extrinsic adiabatic boundaries. Extrinsic adiabatic boundaries include structural adiabatic boundaries and thermal collision adiabatic boundaries.

An effective heat transfer space 194 is defined as a space in which heat is transferred in the +direction of the Z-axis in each heat transfer layer. A side close to the Z-axis and a side far from the Z-axis will be defined as inside and outside, respectively. On a perpendicular cross section with respect to the Z-axis in each z of the n-th heat transfer layer, a plane enclosed by a line connecting intersections with whichever adiabatic boundary line is on the inside between the intrinsic adiabatic boundary line and the extrinsic adiabatic boundary line is defined as the effective heat transfer surface. In addition, in the n-th heat transfer layer, a space constituted of the effective heat transfer surface of each z will be defined as the effective heat transfer space of the n-th heat transfer layer.

In any unit cell Uᵢⱼ (any unit cell Uᵢⱼ means that i and j are any integers) of the single-pulse PSM 1, a length of the chip metal conductor Bᵢⱼ in the X-axis direction is set to a total dimension of 2Lₖ, with dimensions Lₖ on the +side and −side of the X-axis, respectively, centered on the Z-axis. The significance of this is that, in any unit cells Uᵢⱼ that are adjacent to each other in the X-axis direction, aligning the intersections between an intrinsic adiabatic boundary line 184 and an structural adiabatic boundary line 186 and the intersections between the intrinsic adiabatic boundary line 184 and a thermal collision adiabatic boundary line 188 to be described later at the same positions in the Z-axis direction prevents the center of gravity of the heat transfer surface from shifting away from the Z-axis and prevents thermal imbalance from being created in the X-axis direction.

Furthermore, even in the single-pulse PSM 1 to which the simulation calculation according to the present invention is applied, it is advantageous to adopt a structure in which both intersections are aligned in the Z-axis direction. This is because the simulation calculation for an actual single-pulse PSM 1 can be simplified while ensuring consistency between a calculation result of the simulation calculation and the structure of the actual single-pulse PSM 1.

The chip metal conductor Bᵢⱼ has a heat incidence surface 190 and a heat exit surface 192 on the upper surface and the lower surface, respectively. After entering the heat incidence surface 190, heat from the die attach Dᵢⱼ is conducted downward while spreading in the lateral direction (Y-axis direction) at a spread angle of α in the chip metal conductor Bᵢⱼ. A boundary line in a side view of heat transfer that spreads at the spread angle α is considered to be the intrinsic adiabatic boundary line 184.

If a lateral width of the chip metal conductor Bᵢⱼ (2Lₖ in the illustrated example) is sufficient, the intrinsic adiabatic boundary line 184 reaches the lower surface of the chip metal conductor Bᵢⱼ without reaching the side surface (which is also an atmosphere-exposed surface) of the chip metal conductor Bᵢⱼ. However, if the lateral width of the chip metal conductor Bᵢⱼ is not sufficiently large, the intrinsic adiabatic boundary line 184 reaches the side surface of the chip metal conductor Bᵢⱼ at an atmosphere-exposed surface reaching point 196 before reaching the lower surface of the chip metal conductor Bᵢⱼ. The conduction of heat in the chip metal conductor Bᵢⱼ is to proceed toward the lower surface of the chip metal conductor Bᵢⱼ without any heat spread with α=0° on a +side of the atmosphere-exposed surface reaching point 196 in the Z-axis direction on a side of the side surface. In this manner, a boundary line on which downward thermal conduction in the heat transfer layer limits heat spread due to dimensional reasons is referred to as the structural adiabatic boundary line 186. The structural adiabatic boundary line 186 is defined as a boundary line that descends along the side surface or, in other words, parallel to the Z-axis from the atmosphere-exposed surface reaching point 196.

Next, the thermal collision adiabatic boundary line 188 that is an adiabatic boundary when the stacked structure 25 are adjacent to each other will be described. When the stacked structure 25 are adjacent to each other in the lateral direction or the longitudinal direction, in the illustrated example, since the adjacent stacked structure 25 share the third heat transfer layer, a thermal collision occurs in the thermal conduction between the adjacent stacked structures 25. In FIG. 10, the intrinsic adiabatic boundary line 184 of the unit cell Uᵢⱼ intersects with the intrinsic adiabatic boundary line 184 from the side of Uᵢ₊₁ⱼ at a collision point 198 in a side view. As a result, since the +side in the Z-axis direction with respect to the collision point 198 becomes isothermal to the adjacent heat transfer layer, α=0°. In other words, heat is to proceed toward the lower surface of the chip metal conductor Bᵢⱼ without heat spread in the lateral direction on a lower side of the collision point 198. In this manner, a boundary line on which downward thermal conduction in the heat transfer layer has no heat spread due to a collision between intrinsic adiabatic boundary lines 184 of adjacent stacked structures 25 is referred to as the thermal collision adiabatic boundary line 188. The thermal collision adiabatic boundary line 188 is defined as a boundary line that descends parallel to the Z-axis from the atmosphere-exposed surface reaching point 196.

### DEFINITIONS

Various effective heat transfer spaces will be described with reference to FIGS. 11A to 16. While the three-axis orthogonal coordinate system defined with respect to the effective heat transfer spaces has already been partially described with reference to FIG. 10, the three-axis orthogonal coordinate system will be described below once again together with other reference signs.

Origin: a center of an upper surface of a power semiconductor SW chip as a heat transfer layer of the uppermost layer (first heat transfer layer) of a stacked structure
Z-axis: a coordinate axis parallel to the stacked direction of a stacked structure, with downward being a positive orientation
X-axis and Y-axis: coordinate axes parallel to a lateral side and a longitudinal side of a rectangle in a plan view of a power semiconductor SW chip, respectively
x, y, and z: coordinates of the X-axis, the Y-axis, and the Z-axis, respectively
Pₙ: an upper surface of an effective heat transfer space of an n-th heat transfer layer (heat incidence surface 190 in FIG. 10)
Pₙ₊₁: an upper surface of an effective heat transfer space of an n+1-th heat transfer layer (in other words, a lower surface of an effective heat transfer space of Pₙ (heat exit surface 192 in FIG. 10))
P_{nz}: an effective heat transfer face at z of the n-th heat transfer layer
zₙ: a coordinate position of an upper surface of the n-th heat transfer layer
λₙ: thermal conductivity of the n-th heat transfer layer
Lₙ: a distance separating peripheral lines of an effective heat transfer surface P₁ on an upper surface of a first heat transfer layer (semiconductor chip) and an effective heat transfer surface Pₙ on an upper surface of an n-th heat transfer layer when both effective heat transfer surfaces are viewed from the −Z direction
l_{nz} or l_{nz}(z): a distance separating peripheral lines of the effective heat transfer surface Pₙ on the upper surface of the n-th heat transfer layer and an effective heat transfer face Pₙ₊₁ at z of the n-th heat transfer layer when both effective heat transfer surface and face are viewed from the −Z direction
lₙ: a distance separating peripheral lines of the effective heat transfer surface Pₙ on the upper surface of the n-th heat transfer layer and an effective heat transfer surface Pₙ₊₁ on an upper surface of an n+1-th heat transfer layer (semiconductor chip) created on the assumption that the intrinsic adiabatic boundary line 184 of the n-th heat transfer layer has reached the lower surface of the heat transfer layer regardless of the presence or absence of an extrinsic adiabatic boundary line of the heat transfer layer
W_{Z}: an axial line which passes through the peripheral line of the effective heat transfer surface P₁ on the upper surface of the first heat transfer layer (semiconductor chip) in a side view (directional view from the −Y direction) and which is parallel to the Z-axis
βₙ: density or specific gravity of the n-th heat transfer layer
cₙ: specific heat of the n-th heat transfer layer
Cₜₕₙ: thermal capacity of the n-th heat transfer layer
Rₜₕₙ: thermal resistance of the n-th heat transfer layer
Aₙ(z): an area in a plan view of an n-th effective heat transfer space at z
dₙ: thickness (dimension in Z-axis direction) of the n-th heat transfer layer
a and b: lateral width and longitudinal width of P₁ in a plan view

### (First Effective Heat Transfer Space)

FIGS. 11A and 11B are a plan view and a reference sign explanatory diagram with respect to an effective heat transfer space 210 (first effective heat transfer space). The effective heat transfer space 210 is an example of an effective heat transfer space defined only by the intrinsic adiabatic boundary line 184. While a third (n=3) heat transfer layer has been described with reference to FIG. 10 described earlier, n will be described as any number satisfying 1≤n≤m with reference to FIGS. 11A to 16.

All effective heat transfer spaces including the effective heat transfer space 210 are calculated as being isothermal at any internal z in the simulation calculation of a heat transfer amount. This can be understood from the fact that a temperature factor is not included in equations (eq2) and (eq3) for calculating the steady-state thermal capacity Cₜₕₙ and the steady-state thermal resistance Rₜₕₙ described later.

A feature of the effective heat transfer space 210 is that Pₙ is a rectangle with rounded corners in a plan view or, in other words, a rectangle with four corners that are ¼ circles.

When calculating the steady-state thermal capacity Cₜₕₙ and the steady-state thermal resistance Rₜₕₙ of the effective heat transfer space 210 by simulation, the following equations (eq1) to (eq4) are used. Note that the equations (eq1) to (eq4) are not limited to the effective heat transfer space 210 but are equations that can be universally applied to various effective heat transfer spaces when calculating the steady-state thermal capacity Cₜₕₙ and the steady-state thermal resistance Rₜₕₙ of the effective heat transfer spaces by simulation. In other words, the equations (eq1) to (eq4) are also applied to effective heat transfer spaces 220 to 260 to be described later.

l_{nz} or l_{nz}(z) is calculated using the following equation (eq1).

$$\begin{matrix}[ Expression 1 ] & \\ {l}_{nz} = {l}_{nz} ( z ) = \frac{{λ}_{n}}{{λ}_{n + 1}} ( z - {z}_{n} ) & ( eq 1 )\end{matrix}$$

The steady-state thermal capacity Cₜₕₙ is calculated using the following equation (eq2).

$$\begin{matrix}[ Expression 2 ] & \\ {C}_{thn} = {ρ}_{n} {c}_{n} {\int }_{{z}_{n}}^{{z}_{n + 1}} {A}_{n} ( z ) dz & ( eq 2 )\end{matrix}$$

The steady-state thermal resistance Rₜₕₙ is calculated using the following equation (eq3).

$${R}_{thn} = \frac{1}{{λ}_{n}} {\int }_{{z}_{n}}^{{z}_{n + 1}} \frac{dz}{{A}_{n} ( z )} \qquad ( eq 3 )$$

zₙ is calculated using the following equation (eq4).

$${z}_{n} = {\sum }_{k = 1}^{n - 1} {d}_{k} \qquad ( eq 4 )$$

FIG. 11C is a classification explanatory diagram in a plan view of the effective heat transfer space 210 when calculating the steady-state thermal capacity Cₜₕₙ and the steady-state thermal resistance Rihn of the effective heat transfer space 210 by simulation. Specifically, an area Aₙ(z) at a given depth of the effective heat transfer space 210 can be divided into one partial area A, two partial areas B1, two partial areas B2, and four partial areas C as a first model. A denotes a portion directly below rectangular P1 in Pₙ and is a rectangle in a plan view. The two Bls are portions of Pₙ having spread on the +side and the −side in the longitudinal direction with respect to A and, when combined, form a rectangle in a plan view. The two B2s are portions of Pₙ having spread on the +side and the −side in the lateral direction with respect to A and, when combined, form a rectangle in a plan view. The four Cs are portions of Pₙ having spread in diagonal directions with respect to A and, when all four are combined, form a circle in a plan view.

In the effective heat transfer space 210, Aₙ(z) in equations (eq2) and (eq3) can be calculated as the sum of the areas of one A, a rectangle constituted of two B1s, a rectangle constituted of two B2s, and a circle constituted of four Cs.

The steady-state thermal capacity Cₜₕₙ in the effective heat transfer space 210 is calculated using the following equation (eq191).

$$\begin{matrix}[ Equation 5 ] & \\ {C}_{thn} = {ρ}_{n} {c}_{n} {π ( \frac{{λ}_{n}}{{λ}_{n + 1}} )}^{2} ( \frac{1}{3} ( {( {z}_{n + 1} - {z}_{n} + \frac{{λ}_{n + 1}}{{λ}_{n}} {L}_{n} )}^{3} - {( \frac{{λ}_{n + 1}}{{λ}_{n}} {L}_{n} )}^{3} ) & ( eq 191 )\end{matrix}$$

$$+ \frac{( a + b )}{π} \frac{{λ}_{n + 1}}{{λ}_{n}} ( {( {z}_{n + 1} - {z}_{n} + \frac{{λ}_{n + 1}}{{λ}_{n}} {L}_{n} )}^{2} - {( \frac{{λ}_{n + 1}}{{λ}_{n}} {L}_{n} )}^{2} )$$

$$+ \frac{ab}{π} {( \frac{{λ}_{n + 1}}{{λ}_{n}} )}^{2} ( ( {z}_{n + 1} - {z}_{n} + \frac{{λ}_{n + 1}}{{λ}_{n}} {L}_{n} ) - \frac{{λ}_{n + 1}}{{λ}_{n}} {L}_{n} ) )$$

The steady-state thermal resistance Rₜₕₙ in the effective heat transfer space 210 is calculated using the following equation (eq192).

$$\begin{matrix}[ Expression 6 ] & \\ {R}_{thn} = \frac{{λ}_{n + 1}^{2}}{π ( {β}_{0} - {y}_{0} ) {λ}_{n}^{3}} ( log \vert \frac{{z}_{n + 1} - {z}_{n} + \frac{{λ}_{n + 1}}{{λ}_{n}} {L}_{n} - {β}_{0}}{{z}_{n + 1} - {z}_{n} + \frac{{λ}_{n + 1}}{{λ}_{n}} {L}_{n} - {γ}_{0}} \vert - log \vert \frac{\frac{{λ}_{n + 1}}{{λ}_{n}} {L}_{n} - {β}_{0}}{\frac{{λ}_{n + 1}}{{λ}_{n}} {L}_{n} - {γ}_{0}} \vert ) & ( eq 192 )\end{matrix}$$

β₀ and γ₀ are defined by the following equations (eq193) and (eq194). Specifically, β₀ and γ₀ are solutions of a quadratic equation with respect to X defined by equation (eq193) by setting the equation for Aₙᵢ (eq194) to 0. Note that the subscript “i” in Aₙᵢ expresses intrinsicality.

$$\begin{matrix}[ Expression 7 ] & \\ X = z - {z}_{n} + \frac{{λ}_{n + 1}}{{λ}_{n}} {L}_{n} & ( eq 193 )\end{matrix}$$

$${A}_{ni} ( z ) = π {( \frac{{λ}_{n}}{{λ}_{n + 1}} )}^{2} \{ {X}^{2} + \frac{2 ( a + b )}{π} \frac{{λ}_{n + 1}}{{λ}_{n}} X + \frac{ab}{π} {( \frac{{λ}_{n + 1}}{{λ}_{n}} )}^{2} \} \qquad ( eq 194 )$$

### (Second Effective Heat Transfer Space)

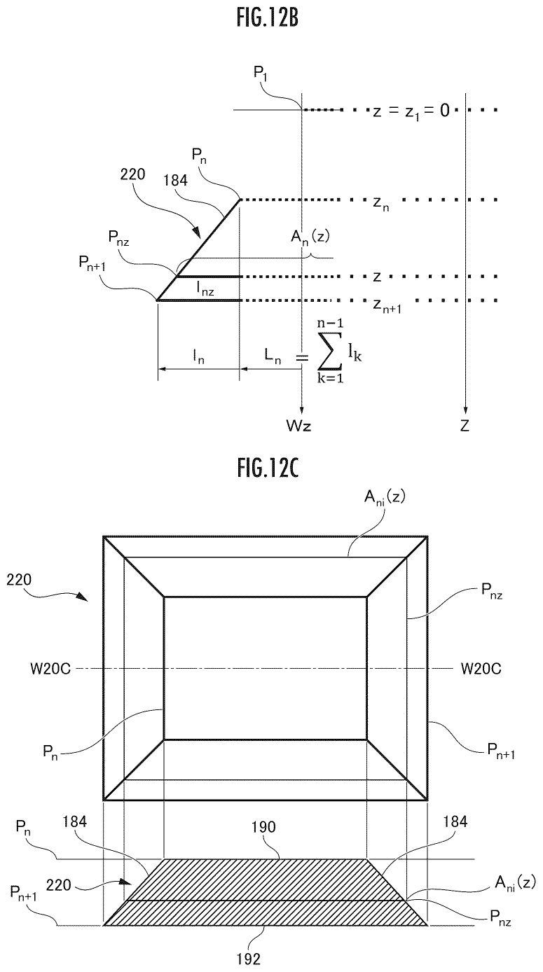

FIGS. 12A, 12B, and 12C are a plan view, a reference sign explanatory diagram, and a lateral sectional view with respect to an effective heat transfer space 220 (second effective heat transfer space), respectively. In FIG. 12C, a lower sectional view is a sectional view taken along W20C-W20C in an upper plan view. A feature of the effective heat transfer space 220 is that Pₙ and Pₙ₊₁ are rectangles with right-angled corners in a plan view. The effective heat transfer space 220 is also an example of an effective heat transfer space defined only by the intrinsic adiabatic boundary line 184 in a similar manner to the effective heat transfer space 210.

In the effective heat transfer space 220, the following equation (eq201) is applied as the steady-state thermal capacity Cₜₕₙ in equation (eq2).

$$\begin{matrix}[ Expression 8 ] & \\ {C}_{thn} = {ρ}_{n} {c}_{n} α ( \frac{1}{3} ( {z}_{n + 1}^{3} - {z}_{n}^{3} ) + \frac{1}{2} ( β + γ ) ( {z}_{n + 1}^{2} - {z}_{n}^{2} ) + β γ ( {z}_{n + 1} - {z}_{n} ) ) & ( eq 201 )\end{matrix}$$

In the effective heat transfer space 220, the following equation (eq202) or (eq203) is applied as the steady-state thermal resistance Rₜₕₙ in equation eq3.

$$\begin{matrix}[ Expression 9 ] & \\ When a \neq b ( β \neq γ ) {R}_{thn} = \frac{1}{α ( β - y ) {λ}_{n}} log \frac{( {z}_{n + 1} - β ) ( {z}_{n} - γ )}{( {z}_{n + 1} - γ ) ( {z}_{n} - β )} & ( eq 202 )\end{matrix}$$

$$When a = b ( β \neq γ ) {R}_{thn} = \frac{1}{{αλ}_{n}} \frac{( {z}_{n + 1} - {z}_{n} )}{( {z}_{n + 1} - β ) ( {z}_{n} - β )} \qquad ( eq 203 )$$

Note that β and γ are solutions of an equation of z by setting the following equation (eq204) to 0, where Aₙᵢ(z)=Aₙ(z).

$$\begin{matrix}[ Equation 10 ] & \\ {A}_{ni} ( z ) & ( eq 204 )\end{matrix}$$

$$= 4 {( \frac{{λ}_{n}}{{λ}_{n + 1}} )}^{2} ( z - {z}_{n} + \frac{{λ}_{n + 1}}{{λ}_{n}} ( {L}_{n} a ) ) ( z - {z}_{n}$$

$$+ \frac{{λ}_{n + 1}}{{λ}_{n}} ( {L}_{n} + \frac{b}{2} ) )$$

$$α = 4 {( \frac{{λ}_{n}}{{λ}_{n + 1}} )}^{2} \qquad ( eq 205 )$$

$$β = {z}_{n} - \frac{{λ}_{n + 1}}{{λ}_{n}} ( {L}_{n} + \frac{a}{2} ) \qquad ( eq 206 )$$

$$γ = {z}_{n} - \frac{{λ}_{n + 1}}{{λ}_{n}} ( {L}_{n} + \frac{b}{2} ) \qquad ( eq 207 )$$

While the classification explanatory diagram in a plan view in FIG. 11C described with respect to the effective heat transfer space 210 is omitted with respect to the effective heat transfer space 220, only the ¼ circles of the four Cs in FIG. 11C have been replaced with ¼ squares in the classification in a plan view of the effective heat transfer space 220. Therefore, in the effective heat transfer space 220 has a second model, when calculating Aₙ(z) of the equations (eq2) and (eq3), the calculations can be smoothly performed by combining the ¼ squares of the corners into a single square in a plan view instead of combining the four Cs of the effective heat transfer space 210 into a circle in a plan view.

### (Third Effective Heat Transfer Space)

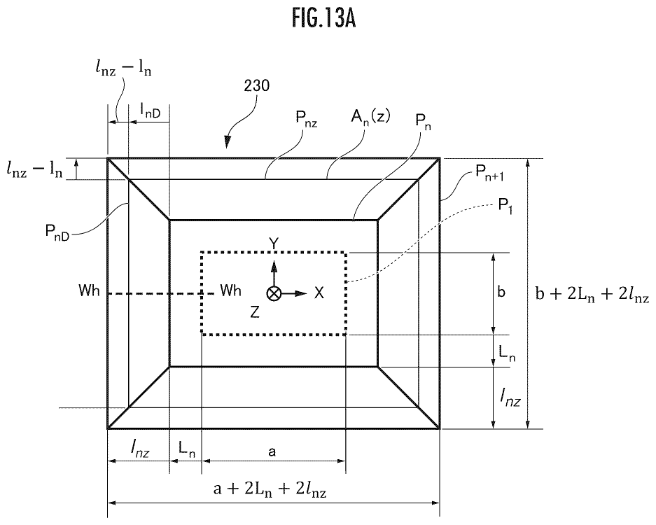

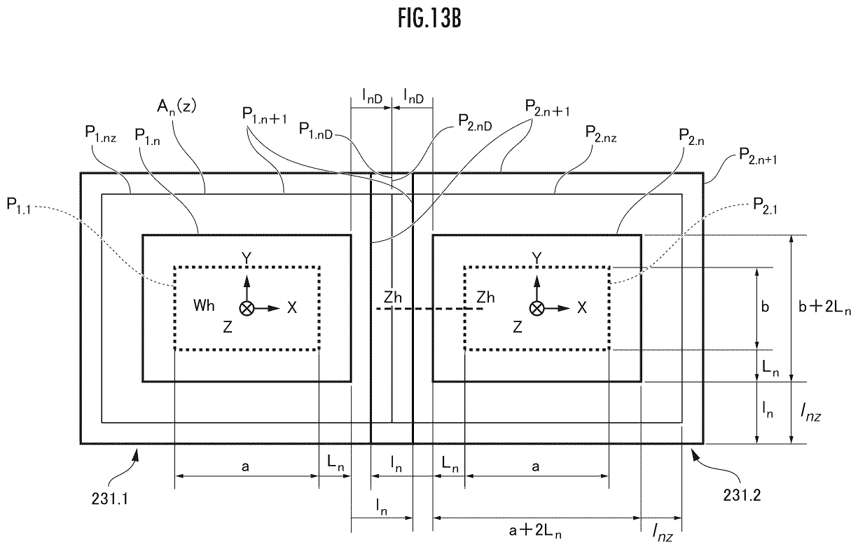

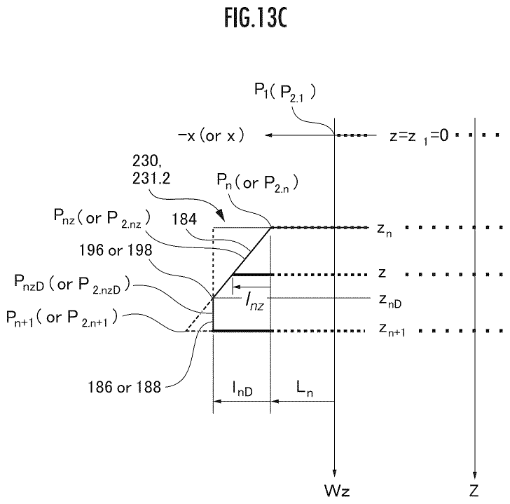

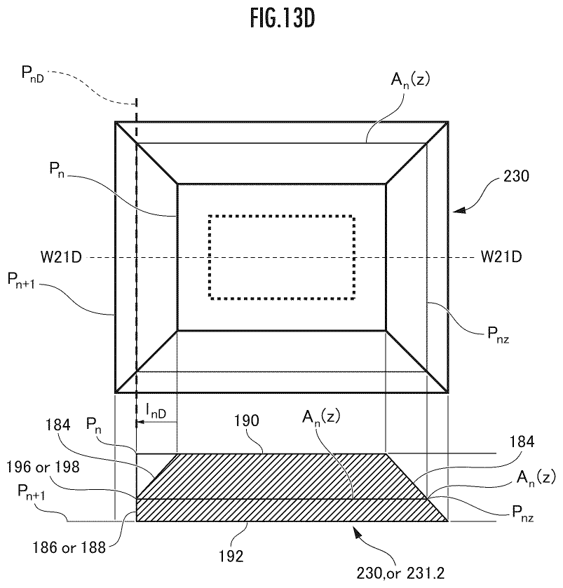

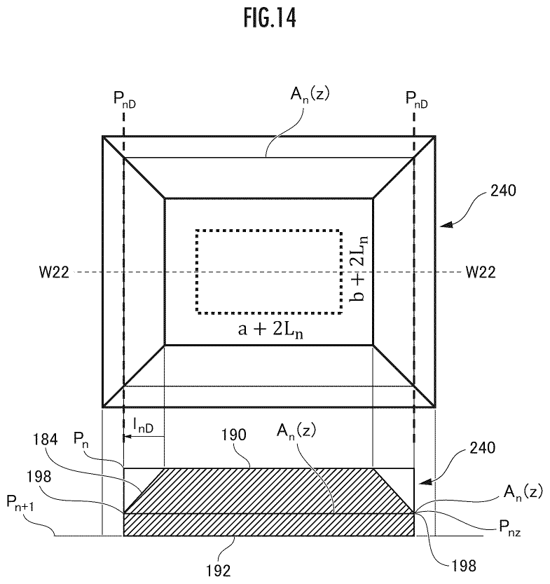

FIG. 13A is a plan view with respect to an effective heat transfer space 230 (third effective heat transfer space). A feature of the effective heat transfer space 230 is that the effective heat transfer space 230 has the structural adiabatic boundary line 186 as an extrinsic adiabatic boundary in addition to the intrinsic adiabatic boundary line 184. Such a case occurs when the lateral width of the n-th heat transfer layer is insufficient on one side in the lateral direction as explained in the structural adiabatic boundary line 186 in FIG. 10.

In P_{nz} in which the lateral width of the effective heat transfer space 230 has been extended by I_{nD} from Pₙ that is rectangular in a plan view on each side of the four sides of Pₙ, the intrinsic adiabatic boundary line 184 reaches the atmosphere-exposed surface reaching point 196 on one side of the effective heat transfer space 230 in the lateral direction. On this side, since a heat transfer layer is not present on an outer side in the lateral direction, the effective heat transfer space 230 descends parallel to the Z-axis down to Pₙ₊₁ without spreading in the lateral direction in the range below the atmosphere-exposed surface reaching point 196.

FIG. 13B is a plan view with respect to effective heat transfer spaces 231.1 and 231.2 (other third effective heat transfer spaces). A feature of the effective heat transfer spaces 231.1 and 231.2 is that the effective heat transfer spaces 231.1 and 231.2 have a thermal collision adiabatic boundary line 188 at center of the spaces in addition to the intrinsic adiabatic boundary line 184.

The power semiconductor SW chips each having P1.1 and P1.2 are adjacent to each other in the lateral direction, and 2l_{nD} that is a lateral spacing between a right side of P1.1 and a left side of P1.2 is 2l_{nD}<2ln. As a result, the intrinsic adiabatic boundary line 184 of P1.1 and the intrinsic adiabatic boundary line 184 of P1.2 intersect on the thermal collision adiabatic boundary line 188. Note that z of the intersection is z_{nD}, where l_{nz} in the effective heat transfer spaces 230 and 231.2 is l_{nz}=l_{nD}.

FIG. 13C shows a dimension of each part of the effective heat transfer space 230 or the effective heat transfer space 231.2 in a side view. FIG. 13D shows a correspondence relationship between a plan view and a side view of the effective heat transfer space 230 or the effective heat transfer space 231.2. In FIG. 13D, a lower sectional view in a side view is a sectional view cut along W21D-W21D in the upper view.

In the effective heat transfer spaces 230 and 231.1 and the effective heat transfer space 231.2, the following equation (eq211) is applied as the steady-state thermal capacity Cₜₕₙ in equation (eq2).

$$\begin{matrix}[ Expression 11 ] & \\ {C}_{thn} = {ρ}_{n} {c}_{n} \{ α ( \frac{1}{3} ( {z}_{nD}^{3} - {z}_{n}^{3} ) + \frac{1}{2} ( β + γ ) ( {z}_{nD}^{2} - {z}_{n}^{2} ) + βγ ( {z}_{nD} - {z}_{n} ) ) + {α}_{1} ( \frac{1}{3} ( {z}_{n + 1}^{3} - {z}_{nD}^{3} ) + \frac{1}{2} ( {β}_{1} + {γ}_{1} ) ( {z}_{n + 1}^{2} - {z}_{nD}^{2} ) + {β}_{1} {γ}_{1} ( {z}_{n + 1} - {z}_{nD} ) ) \} & ( eq 211 )\end{matrix}$$

In the effective heat transfer spaces 230 and 231.1 and the effective heat transfer space 231.2, the following equations (eq212) to (eq215) are applied as the steady-state thermal resistance Rₜₕₙ in equation (eq3).

$$\begin{matrix}[ Expression 12 ] & \\ When β \neq γ ( a \neq b ) and {β}_{1} \neq {γ}_{1} & \end{matrix}$$

$${R}_{thn} = \frac{1}{α ( β - γ ) {λ}_{n}} log \frac{( {z}_{nD} - β ) ( {z}_{n} - γ )}{( {z}_{nD} - γ ) ( {z}_{n} - β )} + \frac{1}{{α}_{1} ( {β}_{1} - {γ}_{1} ) {λ}_{n}} log \frac{( {z}_{n + 1} - {β}_{1} ) ( {z}_{nD} - {γ}_{1} )}{( {z}_{n + 1} - {γ}_{1} ) ( {z}_{nD} - {β}_{1} )} \qquad ( eq 212 )$$

$$When β \neq γ ( a \neq b ) and {β}_{1} = {γ}_{1}$$

$${R}_{thn} = \frac{1}{α ( β - γ ) {λ}_{n}} log \frac{( {z}_{nD} - β ) ( {z}_{n} - γ )}{( {z}_{nD} - γ ) ( {z}_{n} - β )} + \frac{1}{{α}_{1} {λ}_{n}} \frac{( {z}_{n + 1} - {z}_{nD} )}{( {z}_{n + 1} - {β}_{1} ) ( ( {z}_{nD} - {β}_{1} ) )} \qquad ( eq 213 )$$

$$When β = γ ( a = b ) and {β}_{1} \neq {γ}_{1}$$

$${R}_{thn} = \frac{1}{{αλ}_{n}} \frac{( {z}_{nD} - {z}_{n} )}{( {z}_{nD} - β ) ( ( {z}_{n} - β ) )} + \frac{1}{{α}_{1} ( {β}_{1} - {γ}_{1} ) {λ}_{n}} log \frac{( {z}_{n + 1} - {β}_{1} ) ( {z}_{nD} - {γ}_{1} )}{( {z}_{n + 1} - {γ}_{1} ) ( {z}_{nD} - {β}_{1} )} \qquad ( eq 214 )$$

$$When β = γ ( a = b ) and {β}_{1} = {γ}_{1}$$

$$∴ {R}_{thn} = \frac{1}{{αλ}_{n}} \frac{( {z}_{nD} - {z}_{n} )}{( {z}_{nD} - β ) ( {z}_{n} - β )} + \frac{1}{{α}_{1} {λ}_{n}} \frac{( {z}_{n + 1} - {z}_{nD} )}{( {z}_{n + 1} - {β}_{1} ) ( ( {z}_{nD} - {β}_{1} ) )} \qquad ( ea 215 )$$

However, α₁, β₁, and γ₁ are defined by the following equations (eq216), (eq217), and (eq218), respectively.

$$\begin{matrix}[ Expression 13 ] & \\ {α}_{1} = 2 {( \frac{{λ}_{n}}{{λ}_{n + 1}} )}^{2} & ( eq 216 )\end{matrix}$$

$${β}_{1} = 2 {z}_{n} - {z}_{nD} - \frac{{λ}_{n + 1}}{{λ}_{n}} ( a + 2 {L}_{n} ) \qquad ( eq 217 )$$

$${γ}_{1} = {z}_{n} - \frac{{λ}_{n + 1}}{{λ}_{n}} ( {L}_{n} + \frac{b}{2} ) \qquad ( eq 218 )$$

### (Fourth Effective Heat Transfer Space)

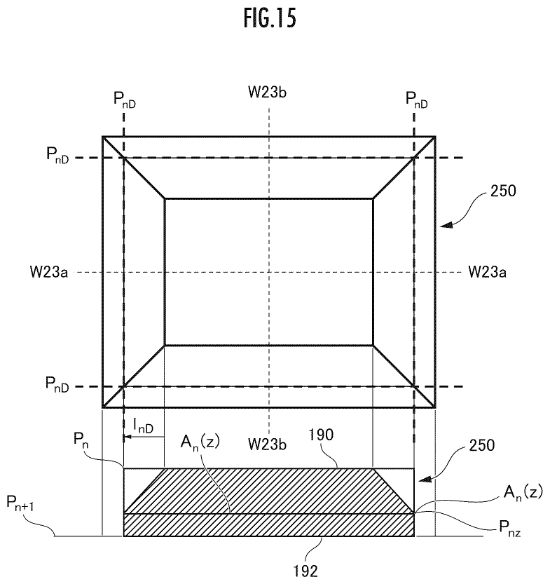

FIG. 14 is a plan view with respect to an effective heat transfer space 240 (fourth effective heat transfer space). In FIG. 14, a lower sectional view is a sectional view taken along W22-W22 in an upper plan view. A feature of the effective heat transfer space 240 is that, unlike the effective heat transfer space 230 (FIG. 13A) described earlier having the thermal collision adiabatic boundary line 188 only on one end side in the lateral direction in a plan view, the effective heat transfer space 240 has the thermal collision adiabatic boundary line 188 on both end sides in the lateral direction.

In the effective heat transfer space 240, the equation (eq221) is applied as the steady-state thermal capacity Cₜₕₙ in equation eq2.

$$\begin{matrix}[ Expression 14 ] & \\ {C}_{thn} = {ρ}_{n} {c}_{n} \{ α ( \frac{1}{3} ( {z}_{nD}^{3} - {z}_{n}^{3} ) + \frac{1}{2} ( β + γ ) ( {z}_{nD}^{2} - {z}_{n}^{2} ) + βγ ( {z}_{nD} - {z}_{n} ) ) + \frac{1}{2} {α}_{2} ( {( {z}_{n + 1} - {γ}_{2} )}^{2} - {( {z}_{nD} - {γ}_{2} )}^{2} ) \} & ( eq 221 )\end{matrix}$$

In the effective heat transfer space 240, the equation (eq222) or (eq223) is applied as the steady-state thermal resistance Rₜₕₙ in equation eq3.

$$\begin{matrix}[ Expression 15 ] & \\ When β \neq γ ( a \neq b ) & \end{matrix}$$

$${R}_{thn} = \frac{1}{α ( β - γ ) {λ}_{n}} log \frac{( {z}_{nD} - β ) ( {z}_{n} - γ )}{( {z}_{nD} - γ ) ( {z}_{n} - β )} + \frac{1}{{α}_{2} {λ}_{n}} log \frac{{z}_{n + 1} - {γ}_{2}}{{z}_{nD} - {γ}_{2}} \qquad ( eq 222 )$$

$$When β = γ ( a = b )$$

$${R}_{thn} = \frac{1}{{αλ}_{n}} \frac{( {z}_{nD} - {z}_{n} )}{( {z}_{nD} - β ) ( {z}_{n} - β )} + \frac{1}{{α}_{2} {λ}_{n}} log \frac{{z}_{n + 1} - {γ}_{2}}{{z}_{nD} - {γ}_{2}} \qquad ( eq 223 )$$

However, α₂ and γ₂ are defined by the following equations (eq224) and (eq225), respectively.

$$\begin{matrix}[ Expression 16 ] & \\ {α}_{2} = 4 {( \frac{{λ}_{n}}{{λ}_{n + 1}} )}^{2} ( {z}_{nD} - {z}_{n} + \frac{{λ}_{n + 1}}{{λ}_{n}} ( {L}_{n} + \frac{a}{2} ) ) & ( eq 224 )\end{matrix}$$

$${γ}_{2} = {z}_{n} - \frac{{λ}_{n + 1}}{{λ}_{n}} ( {L}_{n} + \frac{b}{2} ) \qquad ( eq 225 )$$

### (Fifth Effective Heat Transfer Space)

FIG. 15 is a plan view with respect to an effective heat transfer space 250 (fifth effective heat transfer space). In FIG. 15, a lower sectional view is a sectional view taken along W23-W23 in an upper plan view. A feature of the effective heat transfer space 250 is that, unlike the effective heat transfer space 240 (FIG. 13A) described earlier having the thermal collision adiabatic boundary line 188 only on both end sides in the lateral direction in a plan view, the effective heat transfer space 250 has the thermal collision adiabatic boundary line 188 on not only both end sides in the lateral direction but also on both end sides in the longitudinal direction.

However, in the effective heat transfer space 250, the thermal collision adiabatic boundary lines 188 on both end sides in the lateral direction and the thermal collision adiabatic boundary lines 188 on both end sides in the longitudinal direction are within a same range in the Z-axis direction. In other words, intersections of the intrinsic adiabatic boundary line 184 and the thermal collision adiabatic boundary lines 188 have the same z on all of the four sides of the effective heat transfer space 250 that is rectangular in a plan view.

In the effective heat transfer space 250, the following equation (eq231) is applied as the steady-state thermal capacity Cₜₕₙ in equation eq2.

$$\begin{matrix}[ Expression 17 ] & \\ {C}_{thn} = {ρ}_{n} {c}_{n} \{ α ( \frac{1}{3} ( {z}_{nD}^{3} - {z}_{n}^{3} ) + \frac{1}{2} ( β + γ ) ( {z}_{nD}^{2} - {z}_{n}^{2} ) + βγ ( {z}_{nD} - {z}_{n} ) ) + ( a + 2 {L}_{n} + 2 \frac{{λ}_{n}}{{λ}_{n + 1}} ( {z}_{n} + {z}_{nD} ) ) ( b + 2 {L}_{n} + 2 \frac{{λ}_{n}}{{λ}_{n + 1}} ( {z}_{n} + {z}_{nD} ) ) ( {z}_{n + 1} - {z}_{nD} ) \} & ( eq 231 )\end{matrix}$$

In the effective heat transfer space 250, the equation (eq232) or (eq233) is applied as the steady-state thermal resistance Rₜₕₙ in equation eq3.

$$\begin{matrix}[ Expression 18 ] & \\ When β \neq γ ( a \neq b ) & \end{matrix}$$

$${R}_{thn} = \frac{1}{α ( β - γ ) {λ}_{n}} log \frac{( {z}_{nD} - β ) ( {z}_{n} - γ )}{( {z}_{nD} - γ ) ( {z}_{n} - β )} + \frac{1}{{λ}_{n}} ( a + 2 {L}_{n} + 2 \frac{{λ}_{n}}{{λ}_{n + 1}} ( {z}_{n} + {z}_{nD} ) ) ( b + 2 {L}_{n} + 2 \frac{{λ}_{n}}{{λ}_{n + 1}} ( {z}_{n} + {z}_{nD} ) ) ( {z}_{n + 1} - {z}_{nD} ) \qquad ( eq 232 )$$

$$When β = γ ( a = b )$$

$${R}_{thn} = \frac{1}{{αλ}_{n}} \frac{( {z}_{nD} - {z}_{n} )}{( {z}_{nD} - β ) ( {z}_{n} - β )} + \frac{1}{{λ}_{n}} {( a + 2 {L}_{n} + 2 \frac{{λ}_{n}}{{λ}_{n + 1}} ( {z}_{n} + {z}_{nD} ) )}^{2} ( {z}_{n + 1} - {z}_{nD} ) \qquad ( eq 233 )$$

### (Sixth Effective Heat Transfer Space)

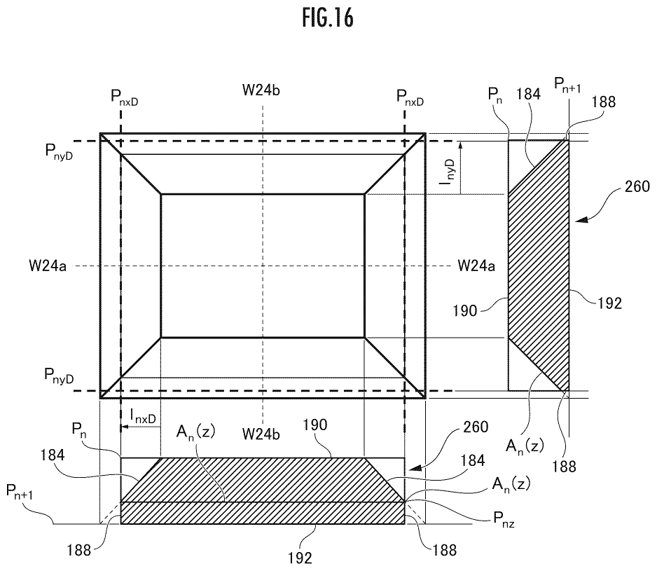

FIG. 16 is a plan view with respect to an effective heat transfer space 260 (sixth effective heat transfer space). In FIG. 16, a lower sectional view is a sectional view taken along W24a-W24a in an upper left plan view. An upper right sectional view is a sectional view taken along W24b-W24b in an upper left plan view. A feature of the effective heat transfer space 260 is that, unlike the effective heat transfer space 250 (FIG. 15) in which the thermal collision adiabatic boundary line 188 on both end sides in the lateral direction and the thermal collision adiabatic boundary line 188 on both end sides in the longitudinal direction are in a same range in the Z-axis direction, in the effective heat transfer space 260, an upper end of the thermal collision adiabatic boundary line 188 on both end sides in the longitudinal direction is positioned lower in the Z-axis direction than an upper end of the thermal collision adiabatic boundary line 188 on both end sides in the lateral direction.

In the effective heat transfer space 260, the following equation (eq241) is applied as the steady-state thermal capacity Cₜₕₙ in equation eq2.

$$\begin{matrix}[ Expression 19 ] & \\ {C}_{thn} = {ρ}_{n} {c}_{n} \{ α ( \frac{1}{3} ( {z}_{nxD}^{3} - {z}_{n}^{3} ) + \frac{1}{2} ( β + γ ) ( {z}_{nxD}^{2} - {z}_{n}^{2} ) + βγ ( {z}_{nxD} - {z}_{n} ) ) + \frac{1}{2} {α}_{3} ( {( {z}_{nyD} - {γ}_{3} )}^{2} - {( {z}_{nxD} - {γ}_{3} )}^{2} ) + ( a + 2 {L}_{n} + 2 \frac{{λ}_{n}}{{λ}_{n + 1}} ( {z}_{n} + {z}_{nyD} ) ) ( b + 2 {L}_{n} + 2 \frac{{λ}_{n}}{{λ}_{n + 1}} ( {z}_{n} + {z}_{nyD} ) ) ( {z}_{n + 1} - {z}_{nyD} ) \} & ( eq 241 )\end{matrix}$$

In the effective heat transfer space 250, the equation (eq242) or (eq243) is applied as the steady-state thermal resistance Rₜₕₙ in equation eq3.

$$\begin{matrix}[ Expression 20 ] & \\ When β \neq γ ( a \neq b ) & \end{matrix}$$

$${R}_{thn} = \frac{1}{α ( β - γ ) {λ}_{n}} log \frac{( {z}_{nxD} - β ) ( {z}_{n} - γ )}{( {z}_{nxD} - γ ) ( {z}_{n} - β )} + \frac{1}{{α}_{3} {λ}_{n}} log \frac{{z}_{nyD} - {γ}_{3}}{{z}_{nxD} - {γ}_{3}} + \frac{{z}_{n + 1} - {z}_{nyD}}{\begin{matrix}{λ}_{n} ( a + 2 {L}_{n} + 2 \frac{{λ}_{n}}{{λ}_{n + 1}} ( {z}_{n} + \\ {z}_{nxD} ) ) ( b + 2 {L}_{n} + 2 \frac{{λ}_{n}}{{λ}_{n + 1}} ( {z}_{n} + {z}_{nyD} ) )\end{matrix}} \qquad ( eq 242 )$$

$$When β = γ ( a = b )$$

$${R}_{thn} = \frac{1}{{αλ}_{n}} \frac{( {z}_{nxD} - {z}_{n} )}{( {z}_{nxD} - β ) ( {z}_{n} - β )} + \frac{1}{{α}_{3} {λ}_{n}} log \frac{{z}_{nyD} - {γ}_{3}}{{z}_{nxD} - {γ}_{3}} + \frac{{z}_{n + 1} - {z}_{nyD}}{{{λ}_{n} ( a + 2 {L}_{n} + 2 \frac{{λ}_{n}}{{λ}_{n + 1}} ( {z}_{n} + {z}_{nxD} ) )}^{2}} \qquad ( eq 243 )$$

However, α₃ and γ₃ are defined by the following equations (eq244) and (eq245), respectively.

$$\begin{matrix}[ Expression 21 ] & \\ {α}_{3} = 4 {( \frac{{λ}_{n}}{{λ}_{n + 1}} )}^{2} ( {z}_{nxD} - {z}_{n} + \frac{{λ}_{n + 1}}{{λ}_{n}} ( {L}_{n} + \frac{a}{2} ) ) & ( eq 244 )\end{matrix}$$

$${γ}_{3} = {z}_{n} - \frac{{λ}_{n + 1}}{{λ}_{n}} ( {L}_{n} + \frac{b}{2} ) \qquad ( eq 245 )$$

### (Calculation of Area of Effective Heat Transfer Surface)

For the effective heat transfer spaces 220, 230.1, 230.2, 240, and 250, an area of an effective heat transfer surface thereof is calculated as a third model, with the effective heat transfer spaces 220, 230.1, 230.2, 240, and 250 as an n-th effective heat transfer space of which at least one side of a rectangle in a plan view overlaps with the extrinsic adiabatic boundary line in a plan view.

Specifically, an area of the effective heat transfer surface used as the basis for calculating Cₜₕₙ and Rₜₕₙ of the effective heat transfer space of the third model is calculated on the assumption that all four sides of the rectangle are spread outward at equal heat spread angles in a range above z_{K} (FIG. 10) where the intrinsic adiabatic boundary line 184, the structural adiabatic boundary line 186, and the thermal collision adiabatic boundary line 188 intersect (refer to plan views in FIGS. 13D, 14, 15, and 16). In addition, an area is calculated on the assumption that a side containing z_{K} does not spread outward in a range below z_{K} (refer to sectional views in FIGS. 13D, 14, 15, and 16).

### (Simulation Method)

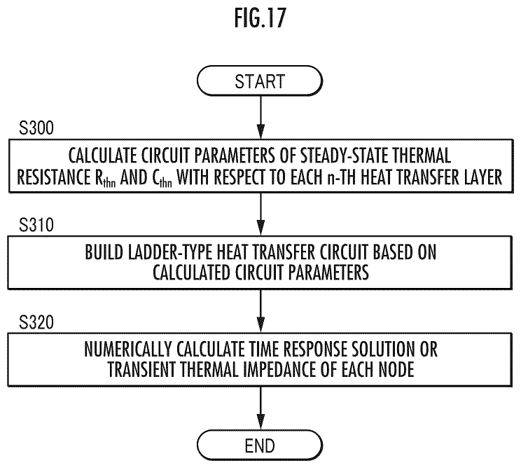

FIG. 17 is a flow chart of a heat transfer simulation method for a power semiconductor switching module. In step S300, circuit parameters of the steady-state thermal resistance Rₜₕₙ and the steady-state thermal capacity Cₜₕₙ of the ladder-type heat transfer circuit 12 with respect to an n-th heat transfer layer for each n are calculated. Specific calculation methods are as described in, for example, effective heat transfer spaces 210 to 260.

In step S310, the ladder-type heat transfer circuit 12 (FIG. 4) is built based on the calculated circuit parameters.

In step S320, a time response solution or a transient thermal impedance of each node in the built ladder-type heat dissipation circuit 12 is numerically calculated using a circuit simulator (for example, SPICE) or the like.

In this manner, as a first step of early steps in which there are many parameters to consider when producing small quantities of the single-pulse PSMs 1 or custom-made single-pulse PSMs 1, trends in changes to transient thermal impedance characteristics can be understood while continuously varying material parameters and structural parameters over a wide range using a simplified simulation, and an optimal structure of a PSM can be roughly designed. As a result, product costs and development and manufacturing periods can be reduced.

### REFERENCE SIGNS LIST

Uᵢⱼ unit cell, Sᵢⱼ power semiconductor SW chip, Dᵢⱼ die attach, Bᵢⱼ chip metal conductor, Mᵢⱼ heat transfer bonding material, Cₜₕₙ steady-state thermal capacity, Rₜₕₙ steady-state thermal resistance, 1 single-pulse PSM, 2 insulating substrate, 10 heat flow single-pulse source, 12 ladder-type heat dissipation circuit, 15 thermal resistance circuit, 16 thermal capacity circuit, 20 atmospheric temperature circuit, 25 stacked structure, 184 intrinsic adiabatic boundary line, 186 structural adiabatic boundary line, 188 thermal collision adiabatic boundary line, 190 heat incidence surface, 192 heat exit surface, 194 effective heat transfer space, 196 atmosphere-exposed surface reaching point, 198 collision point, 210, 220, 230, 231.1, 231.2, 240, 250, 260 effective heat transfer space.

1. A heat transfer simulation method for a power semiconductor switching module comprising:
a stacked structure constituted of m-number (where m is an integer greater than or equal to 2) heat transfer layers, with a power semiconductor SW chip as an uppermost heat transfer layer, in which heat generated by the power semiconductor SW chip is released from an atmosphere-exposed surface of each heat transfer layer, wherein
a ladder-type heat dissipation circuit associated with the stacked structure comprises:
when a steady-state thermal resistance R and a steady-state thermal capacity C of an n-th (where 1≤n≤m) heat transfer layer in a stacking order from the top of the stacked structure are defined as Rₜₕₙ and Cₜₕₙ, respectively, one longitudinal circuit as a thermal resistance circuit in which the steady-state thermal resistance Rₜₕₙ of each heat transfer layer is connected in series in the stacking order from one end to another end;
another longitudinal circuit as an atmospheric temperature circuit;
a heat flow single-pulse source that is interposed between one end of the one longitudinal circuit and one end of the other longitudinal circuit and that serves as a heat source for heat generated by the power semiconductor SW chip; and
a plurality of lateral circuits, each of which interposing, with one end of each steady-state thermal resistance Rₜₕₙ of the one longitudinal circuit as a node, the steady-state thermal capacity Cₜₕₙ of the heat transfer layer of the steady-state thermal resistance Rₜₕₙ between the node and the other longitudinal circuit as a thermal capacity circuit, the heat transfer simulation method comprising:
a circuit parameter calculation step of calculating, for each n, circuit parameters of the steady-state thermal resistance Rₜₕₙ and the steady-state thermal capacity Cₜₕₙ of the ladder-type heat transfer circuit with respect to an n-th heat transfer layer based on heat transfer in a stacked direction of the stacked structure and heat transfer due to a heat spread in a perpendicular direction with respect to the stacked direction;
a ladder-type heat transfer circuit building step of building the ladder-type heat transfer circuit based on the calculated circuit parameters; and
a numerical calculation step of numerically calculating a time response solution or a transient thermal impedance of each node in the built ladder-type heat transfer circuit.

2. The heat transfer simulation method for a power semiconductor switching module according to claim 1, wherein
in the circuit parameter calculation step, the heat spread at each up-down direction position in the n-th heat transfer layer is calculated based on λₙ/λₙ₊₁ and the up-down direction position in the n-th heat transfer layer, where λₙ and Δₙ₊₁ are defined as thermal conductivity of the n-th and n+1-th heat transfer layers.

3. The heat transfer simulation method for a power semiconductor switching module according to claim 1, comprising:
defining a three-axis orthogonal coordinate system with a center of an upper surface of the first heat transfer layer of the stacked structure as an origin, an up-down direction with downward as positive as a Z-axis, and two axial directions that are perpendicular directions with respect to the Z-axis and mutually orthogonal at the origin as X-axis and Y-axis directions, and defining coordinates of the three-axis orthogonal coordinate system as (x, y, z);
setting adiabatic boundary lines in an n-th heat transfer layer for each n,
the adiabatic boundary lines including, when a near side and a far side with respect to the Z-axis are defined as inside and outside, respectively, an intrinsic adiabatic boundary line that proceeds toward the outside as z increases in the n-th heat transfer layer, and an extrinsic adiabatic boundary line fixed at a constant distance from the Z-axis regardless of an increase in z, and
in the numerical calculation step,
defining, on a perpendicular cross section with respect to the Z-axis in each z of the n-th heat transfer layer, a plane enclosed by a line connecting intersections with whichever adiabatic boundary line is on the inside between the intrinsic adiabatic boundary line and the extrinsic adiabatic boundary line as an effective heat transfer surface,
defining, in the n-th heat transfer layer, a space constituted of the effective heat transfer surface of each z as an effective heat transfer space of the n-th heat transfer layer, and
performing a numerical calculation of steady-state heat transfer, which forms a basis for a numerical calculation of a time response solution or a transient thermal impedance of an n+1-th node, by calculating a heat transfer temperature at each effective heat transfer surface in the effective heat transfer space of each heat transfer layer from first to n-th, in order from an upper effective heat transfer surface to a lower effective heat transfer surface and assuming that each effective heat transfer surface is isothermal across its entire surface.

4. The heat transfer simulation method for a power semiconductor switching module according to claim 3, wherein
the extrinsic adiabatic boundary line includes, when the X-axis direction and the Y-axis direction are assumed to be a lateral direction and a longitudinal direction, a structural adiabatic boundary line defined by a lateral width or a longitudinal width of each heat transfer layer and a thermal collision adiabatic boundary line defined by (x, y) of an intersection of two intrinsic adiabatic boundary lines adjacent in the longitudinal direction or the lateral direction, and
in the numerical calculation step, an innermost adiabatic boundary line among the intrinsic adiabatic boundary line, the structural adiabatic boundary line, and the thermal collision adiabatic boundary line is adopted as an effective adiabatic boundary line.

5. The heat transfer simulation method for a power semiconductor switching module according to claim 4, wherein
the numerical calculation of steady-state heat transfer is applied to a reality model in which an n-th heat transfer layer having both the structural adiabatic boundary line and the thermal collision adiabatic boundary line is set to a heat transfer layer in which a z range where the effective adiabatic boundary line is the structural adiabatic boundary line and a z range where the effective adiabatic boundary line is the thermal collision adiabatic boundary line are equal.

6. The heat transfer simulation method for a power semiconductor switching module according to claim 4, comprising defining each reference sign as follows:
zₙ: a coordinate position of an upper surface of an n-th heat transfer layer
λₙ: thermal conductivity of the n-th heat transfer layer
l_{nz} or l_{nz}(z): a distance by which an effective heat transfer surface at z in the n-th heat transfer layer in a side view has spread outward from an effective heat transfer surface of zₙ, and
calculating, in the numerical calculation step, l_{nz} or l_{nz}(z) of z of the n-th heat transfer layer for each n using the following equation (eq1).
$$\begin{matrix}[ Expression 1 ] & \\ {l}_{nz} = {l}_{nz} ( z ) = \frac{{λ}_{n}}{{λ}_{n + 1}} ( z - {z}_{n} ) & ( eq 1 )\end{matrix}$$

7. The heat transfer simulation method for a power semiconductor switching module according to claim 5, comprising further defining each reference sign as follows:
βₙ: specific gravity of the n-th heat transfer layer
cₙ: specific heat of the n-th heat transfer layer
Aₙ(z): area in a plan view at z of the n-th heat transfer layer
dₙ: thickness (dimension in Z-axis direction) of the n-th heat transfer layer,
calculating the steady-state thermal capacity Cₜₕₙ using the following equation (eq2),
$$\begin{matrix}[ Expression 2 ] & \\ {C}_{thn} = {ρ}_{n} {c}_{n} {\int }_{{z}_{n}}^{{z}_{n + 1}} {A}_{n} ( z ) dz & ( eq 2 )\end{matrix}$$
calculating the steady-state thermal resistance Rₜₕₙ using the following equation (eq3), and
$$\begin{matrix}[ Expression 3 ] & \\ {R}_{thn} = \frac{1}{{λ}_{n}} {\int }_{{z}_{n}}^{{z}_{n + 1}} \frac{dz}{{A}_{n} ( z )} & ( eq 3 )\end{matrix}$$
calculating zₙ using the following equation (eq4).
$$\begin{matrix}[ Expression 4 ] & \\ {z}_{n} = {\sum }_{k = 1}^{n - 1} {d}_{k} & ( eq 4 )\end{matrix}$$

8. The heat transfer simulation method for a power semiconductor switching module according to claim 7, comprising:
applying a rectangular first model of which a heat incidence surface as an upper surface in a plan view has four corners with rounded edges to an n-th effective heat transfer space, wherein
Cₜₕₙ and Rₜₕₙ of an effective heat transfer space of the first model includes calculating an area of the effective heat transfer surface by dividing the area into four areas such as a central rectangle positioned at center in a plan view of the first model, a circle formed by combining the rounded edges of the four corners, a longitudinal rectangle that combines two rectangles adjacent to the central rectangle on both sides in the longitudinal direction, and a lateral rectangle that combines two rectangles adjacent to the central rectangle on both sides in the lateral direction.

9. The heat transfer simulation method for a power semiconductor switching module according to claim 7, comprising:
applying a rectangular second model of which a heat incidence surface as an upper surface in a plan view has four right-angled corners to an n-th effective heat transfer space, wherein
Cₜₕₙ and Rₜₕₙ of an effective heat transfer space of the second model includes calculating an area of the effective heat transfer surface by dividing the area into four areas such as a central rectangle positioned at center in a plan view, a square formed by combining the right-angled portions of the four corners, a longitudinal rectangle that combines two rectangles adjacent to the central rectangle on both sides in the longitudinal direction, and a lateral rectangle that combines two rectangles adjacent to the central rectangle on both sides in the lateral direction.

10. The heat transfer simulation method for a power semiconductor switching module according to claim 7, comprising:
applying a third model to an n-th effective heat transfer space that is a rectangle in a plan view and at least one side overlaps with the extrinsic adiabatic boundary line in a plan view, wherein
an area of an effective heat transfer surface used as a basis for calculating Cₜₕₙ and Rₜₕₙ of an effective heat transfer space of the third model is calculated on the assumption that all four sides of the rectangle are spread outward at equal heat spread angles in a range above z_{K} where the intrinsic adiabatic boundary line and the extrinsic adiabatic boundary line intersect and calculated on the assumption that a side containing z_{K} does not spread outward in a range below z_{K}.
